(19) United States
(12) Patent Application Publication
(10) Pub. No.: US 2025/0230358 A1
(43) Pub. Date: Jul. 17, 2025

(54) COMPOSITION, METHOD FOR TREATING OBJECT TO BE TREATED, AND METHOD FOR MANUFACTURING SEMICONDUCTOR DEVICE

(71) Applicant: FUJIFILM CORPORATION, Tokyo (JP)

(72) Inventors: Atsushi Mizutani, Shizuoka (JP); Tomonori Takahashi, Shizuoka (JP); Moe Narita, Shizuoka (JP)

(21) Appl. No.: 19/058,664

(22) Filed: Feb. 20, 2025

Related U.S. Application Data
(63) Continuation of application No. PCT/JP2023/029251, filed on Aug. 10, 2023.

(30) Foreign Application Priority Data
Aug. 31, 2022 (JP) 2022-138245

(51) Int. Cl. C09K 13/06; H01L 21/3213

(52) U.S. Cl. CPC C09K 13/06; H01L 21/32134

(57) ABSTRACT

The present invention provides a composition having excellent Ru removability, a method for treating an object to be treated using the composition, and a method for manufacturing a semiconductor device. The composition according to the embodiment of the present invention includes periodic acid or a salt thereof, a quaternary ammonium salt, at least one ionic surfactant selected from the group consisting of an anionic surfactant, a cationic surfactant, and an amphoteric surfactant, and a nonionic surfactant.

### CROSS-REFERENCE TO RELATED APPLICATIONS

This application is a Continuation of PCT International Application No. PCT/JP2023/029251 filed on Aug. 10, 2023, which claims priority under 35 U.S.C. § 119(a) to Japanese Patent Application No. 2022-138245 filed on Aug. 31, 2022. The above applications are hereby expressly incorporated by reference, in their entirety, into the present application.

### BACKGROUND OF THE INVENTION

### 1. Field of the Invention

The present invention relates to a composition, a method for treating an object to be treated, and a method for manufacturing a semiconductor device.

### 2. Description of the Related Art

In a case of forming circuits and elements, it is common to carry out an etching process using a chemical liquid. In this case, since a plurality of materials may be present on a substrate, it is desirable that the chemical liquid used for etching is a chemical liquid capable of selectively removing only a specific material.

In recent years, ruthenium (hereinafter, also simply referred to as “Ru”) has been used as an electrode material, a wiring material, and the like of a semiconductor element, and it is necessary to carry out a process of removing Ru present in an unnecessary portion, as in the case of other wiring materials. In the process of removing Ru, a chemical liquid is often used.

For example, US2017/0260449A discloses a composition which can selectively remove residues derived from titanium nitride and a resist film on a semiconductor substrate having copper, tungsten, a Low-k material, titanium nitride, and a resist film, the composition containing an oxidant, an etchant, and a solvent, and substantially not containing hydrogen peroxide.

### SUMMARY OF THE INVENTION

Here, as a result of studying the characteristics of the composition described in US2017/0260449A, the inventors of the present invention found that, in a case where an object to be treated containing ruthenium (Ru) is treated with the composition, the removability of ruthenium (hereinafter, also simply referred to as “Ru removability”) is not sufficient, and further improvement is required.

Therefore, an object of the present invention is to provide a composition having excellent Ru removability.

In addition, another object of the present invention is to provide a method for treating an object to be treated, which uses the composition, and a manufacturing method for a semiconductor device.

As a result of extensive studies to achieve the foregoing objects, the present inventors have completed the present invention. That is, the present inventors have found that the foregoing objects can be achieved by the following configurations.
[1] A composition comprising: a periodic acid or a salt thereof; at least one ionic surfactant selected from the group consisting of a quaternary ammonium salt, an anionic surfactant, a cationic surfactant, and an amphoteric surfactant; and a nonionic surfactant.
[2] The composition according to [1], in which the ionic surfactant is an anionic surfactant.
[3] The composition according to [1] or [2], in which the anionic surfactant has at least one of a sulfonic acid group or a phosphoric acid group.
[4] The composition according to any one of [1] to [3], in which the anionic surfactant has a cyclic structure.
[5] The composition according to any one of [1] to [4], in which the nonionic surfactant includes a polyoxyalkylene alkyl ether, a polyoxyalkylene alkyl aryl ether, or a fatty acid ester.
[6] The composition according to any one of [1] to [5], in which the nonionic surfactant has a polyoxyalkylene chain composed of an oxyalkylene group selected from the group consisting of an oxyethylene group and an oxypropylene group.
[7] The composition according to any one of [1] to [6], in which the nonionic surfactant has a polyoxyethylene chain or a polyoxypropylene chain.
[8] The composition according to any one of [1] to [7], in which the nonionic surfactant has a monovalent hydrocarbon group having 10 to 18 carbon atoms.
[9] The composition according to any one of [1] to [8], in which the nonionic surfactant has an HLB value of 9.0 to 20.0.
[10] The composition according to any one of [1] to [9], in which the periodic acid or a salt thereof includes at least one selected from the group consisting of orthoperiodic acid, metaperiodic acid, and salts thereof.
[11] The composition described in any one of [1] to [10], in which the quaternary ammonium salt includes at least one compound selected from the group consisting of a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl) trimethylammonium salt, and a triethyl (2-hydroxyethyl) ammonium salt.
[12] The composition according to any one of [1] to [11], further containing water.
[13] The composition described in any one of [1] to [12], in which a pH of the composition is 3.0 to 10.0.
[14] The composition according to any one of [1] to [13], in which the composition does not substantially contain coarse particles.
[15] A method for treating an object to be treated, comprising a step of bringing an object to be treated, which contains ruthenium, ne of [1] to [14].
[16] A method for manufacturing a semiconductor device, comprising the method for treating an object to be treated as described in [15].

According to the present invention, it is possible to provide a composition having excellent Ru removability.

In addition, according to the present invention, it is also possible to provide a method for treating an object to be treated, which is treated using the composition, and a manufacturing method for a semiconductor device.

### BRIEF DESCRIPTION OF THE DRAWINGS

FIG. 1 is a schematic cross-sectional top view showing an example of an object to be treated used in a step A1.

FIG. 2 is a schematic cross-sectional top view showing an example illustrating the object to be treated shown in FIG. 1 that has undergone the step A1.

FIG. 3 is a schematic cross-sectional top view showing another example of the object to be treated used in the step A1.

FIG. 4 is a schematic cross-sectional top view showing an example illustrating the object to be treated shown in FIG. 3 that has undergone the step A1.

FIG. 5 is a schematic view showing an example of an object to be treated used in a step A2.

FIG. 6 is a schematic cross-sectional view showing an example of an object to be treated used in a step A4.

FIG. 7 is a schematic cross-sectional view showing an example of an object to be treated not yet being subjected to dry etching.

FIG. 8 is a schematic cross-sectional view showing another example of the object to be treated used in a step A4.

FIG. 9 is a schematic cross-sectional view showing an example of an object to be treated in which a Ru-containing film is not yet formed.

FIG. 10 is a schematic cross-sectional view showing an example of an object to be treated used in a step A6.

### DESCRIPTION OF THE PREFERRED EMBODIMENTS

Hereinafter, the present invention will be described in more detail.

The description of the configuration requirements described below may be made based on the representative embodiments of the present invention, but the present invention is not limited to such embodiments.

Hereinafter, the meaning of each description in the present specification will be expressed.

In the present specification, numerical ranges represented by “to” include numerical values before and after “to” as lower limit values and upper limit values.

The compound described in the present specification may include a structural isomer, an optical isomer, and an isotope unless otherwise specified. In addition, one kind of structural isomer, optical isomer, or isotope may be contained alone, or two or more kinds thereof may be contained.

In the present specification, regarding the description of a group (atomic group), in a case where whether the group is substituted or unsubstituted is not described, the group includes a group which has a substituent as well as a group which does not have a substituent. For example, an “alkyl group” includes not only an alkyl group (unsubstituted alkyl group) which does not have a substituent but also an alkyl group (substituted alkyl group) which has a substituent.

A bonding direction of a divalent group (for example, —COO—) described in the present specification is not limited unless otherwise specified. For example, in a case where Y in a compound represented by a formula “X-Y-Z” is —COO—, the compound may be “X—O—CO-Z” or “X—CO—O-Z”.

In the present specification, the “total solid content” means the total content of all components contained in a composition other than a solvent such as water and an organic solvent.

In the present specification, “ppm” means “parts-per-million (106)”, “ppb” means “parts-per-billion (10⁻⁹)”, and “ppt” means “parts-per-trillion (10⁻¹²)”.

In the present specification, unless otherwise specified, the weight-average molecular weight (Mw) and the number average molecular weight (Mn) are values obtained by using TSKgel GMHxL, TSKgel G4000HxL, or TSKgel G2000HxL (all of which are manufactured by Tosoh Corporation) as a column, using tetrahydrofuran as an eluent, using a differential refractometer as a detector, using polystyrene as a standard substance, and carrying out conversion using the polystyrene as a standard substance, which has been subjected to measurement with a gel permeation chromatography (GPC) analysis apparatus. In the present specification, unless otherwise specified, the molecular weight of a compound having a molecular weight distribution is a weight-average molecular weight.

### Composition

The composition according to the embodiment of the present invention includes periodic acid or a salt thereof, a quaternary ammonium salt, at least one ionic surfactant selected from the group consisting of an anionic surfactant, a cationic surfactant, and an amphoteric surfactant, and a nonionic surfactant.

The mechanism by which the object of the present invention can be achieved by adopting the above-described configuration of the composition according to the embodiment of the present invention is not necessarily clear, but the present inventors have considered as follows.

In general, a contact angle of a metal material (for example, Cu, Co, Mo, and the like) with water used for a semiconductor substrate is about 20 degrees, and the metal material has relatively good compatibility with an etchant or a cleaning liquid used in a manufacturing process of a semiconductor device, but in a case of Ru, the contact angle with water is about 70 degrees, and the compatibility is poor.

As described above, in a case where the etchant and Ru on the semiconductor substrate have poor compatibility, the contact area between the etchant and the Ru portion is reduced, and thus Ru removability deteriorates. In particular, in a case of cleaning (bevel cleaning) an outer edge portion (bevel portion) of a substrate in a semiconductor substrate, since the cleaning portion is not flat, the contact area with the liquid is further reduced, and thus the decrease in Ru removability is remarkable.

Therefore, in the composition described in US2017/0260449A, the Ru removability on the object to be treated was insufficient. In addition, in a case of removing Ru of the bevel portion, the deterioration of the removal performance was more remarkable.

On the other hand, in the composition according to the embodiment of the present invention, the contact angle of the composition with respect to Ru can be reduced by selecting and combining an appropriate surfactant. As a result, it is considered that the contact area between the composition and the Ru portion can be increased, and sufficient Ru removability can be exhibited for an object to be treated including Ru. In particular, the composition according to the embodiment of the present invention has excellent Ru removability even in a case of being applied to bevel cleaning.

Hereinafter, respective components included in the composition according to the embodiment of the present invention will be described in detail.

### Periodic Acid or Salt Thereof

The composition according to the embodiment of the present invention contains periodic acid or a salt thereof.

Examples of the periodic acid or a salt thereof include orthoperiodic acid (H₅IO₆), metaperiodic acid (HIO₄), and salts thereof (for example, a sodium salt or a potassium salt).

Among these, the periodic acid or a salt thereof is preferably an orthoperiodic acid, an orthoperiodic acid salt, or a metaperiodic acid, and more preferably an orthoperiodic acid.

As the periodic acid or a salt thereof, one kind may be used alone, or two or more kinds may be used in combination.

The content of the periodic acid or a salt thereof is preferably 0.01% to 20.00% by mass, more preferably 0.01% to 15.00% by mass, still more preferably 0.10% to 10.00% by mass, and particularly preferably 0.10% to 5.00% by mass, with respect to the total mass of the composition.

In a case where two or more kinds of periodic acids or salts thereof are used, the total content of the periodic acids or salts thereof is preferably within the above-described preferred range.

As a supply source of the periodic acid or a salt thereof, a commercially available product may be used. As the commercially available product, any of a solid commercially available product or a liquid commercially available product may be used. Examples of the commercially available product in a liquid form include an aqueous solution containing periodic acid or a salt thereof.

The solution obtained by dissolving the above-described solid commercially available product in water and the liquid commercially available product (particularly, an aqueous solution containing periodic acid or a salt thereof) may contain an anion selected from the group consisting of a chloride ion, a bromide ion, a nitrate ion, a sulfate ion, a phosphate ion, and an iodine ion.

In a case of an aqueous solution containing 50% by mass of periodic acid or a salt thereof among the above-described liquid commercially available products, the content of the anion is preferably 10 ppt by mass to 1,000 ppm by mass with respect to the total mass of the aqueous solution.

In addition, even in a solution (concentration of periodic acid or a salt thereof: 50% by mass) obtained by dissolving a solid commercially available product in water, the content of the anion is preferably 10 ppt by mass to 1,000 ppm by mass with respect to the total mass of the aqueous solution.

### Quaternary Ammonium Salt

The composition according to the embodiment of the present invention contains a quaternary ammonium salt. The quaternary ammonium salt is not particularly limited as long as it has a quaternary ammonium cationic moiety in which a nitrogen atom is bonded to four hydrocarbon groups, but it does not have a function as a surfactant and is a compound different from the cationic surfactant described later.

In addition, the quaternary ammonium salt may be a compound having a quaternary ammonium cationic moiety in which a nitrogen atom in a pyridine ring is bonded to a hydrocarbon group (for example, an alkyl group or an aryl group), such as alkylpyridinium.

The number of carbon atoms in the quaternary ammonium cationic moiety of the quaternary ammonium salt is preferably 4 to 20, more preferably 5 to 15, and still more preferably 6 to 20. The above-described carbon atoms refer to the total number of carbon atoms included in the quaternary ammonium cationic moiety, and do not include the number of carbon atoms in the anion forming a salt.

The anionic moiety corresponding to the quaternary ammonium cationic moiety is not particularly limited, and examples thereof include a hydroxide ion, a halide ion (a chloride ion, a bromide ion, a fluoride ion, or an iodide ion), an acetate ion, a carbonate ion, and a sulfate ion.

Among these, the quaternary ammonium salt preferably includes a quaternary ammonium salt represented by Formula (a).

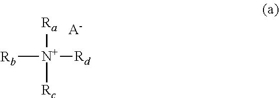

In Formula (a), Rₐ to R_{d} each independently represent an alkyl group which may have a substituent.

The alkyl group may be linear or branched, and is preferably linear. The number of carbon atoms in the alkyl group moiety of the alkyl group is preferably 1 to 10, more preferably 1 to 6, still more preferably 1 to 4, and particularly preferably 1 or 2.

Specific examples of the alkyl group include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, and a hexadecyl group.

Examples of the substituent include a hydroxy group and a phenyl group. Examples of the aspect of the alkyl group having a substituent include a 2-hydroxyethyl group, a 2-hydroxypropyl group, and a benzyl group. In addition, the methylene group constituting the alkyl group may be substituted with a divalent substituent such as —O—.

The total number of carbon atoms contained in Rₐ to R_{d} is not particularly limited, but is preferably 4 to 20, more preferably 5 to 15, and still more preferably 6 to 20.

In addition, the alkyl group which may have two substituents selected from Rₐ to R_{d} may be bonded to each other to form a ring.

In Formula (a), A⁻ represents a monovalent anion.

Examples of the monovalent anion represented by A⁻ include F⁻, Cl⁻, Br⁻, OH⁻, NO₃⁻, CH₃COO⁻, and CH₃CH₂SO₄⁻, and F⁻, Cl⁻, Br⁻, or OH⁻ is preferable, Cl⁻ or OH⁻ is more preferable, and OH⁻ is still more preferable.

Examples of the quaternary ammonium salt represented by Formula (a) include a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a dodecyltrimethylammonium salt, a trimethyltetradecylammonium salt, a hexadecyltrimethylammonium salt, a benzyltrimethylammonium salt, a benzyltriethylammonium salt, a (2-hydroxyethyl) trimethylammonium salt (also referred to as “choline”), a triethyl (2-hydroxyethyl) ammonium salt, a diethylbis (2-hydroxyethyl) ammonium salt, an ethyltris (2-hydroxyethyl) ammonium salt, and a tris (2-hydroxyethyl) methylammonium salt.

Among these, as the quaternary ammonium salt, it is preferable to include at least one selected from the group consisting of a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a ((2-hydroxyethyl) trimethylammonium salt, and a triethyl (2-hydroxyethyl) ammonium salt.

The anion contained in the salt is preferably F⁻, Cl⁻, Br⁻, or OH⁻, more preferably Cl⁻ or OH⁻, and still more preferably OH⁻.

The molecular weight of the quaternary ammonium salt is preferably 90 to 1,000, more preferably 90 to 500, still more preferably 90 to 300, and particularly preferably 90 to 200.

As the quaternary ammonium salt, one kind may be used alone, or two or more kinds may be used in combination.

The total content of the quaternary ammonium salt is preferably 0.01% to 10.00% by mass, more preferably 0.10% to 3.50% by mass, still more preferably 0.30% to 3.00% by mass, and particularly preferably 0.50% to 2.00% by mass with respect to the total mass of the composition.

### Ionic Surfactant

The composition according to the embodiment of the present invention contains at least one ionic surfactant selected from the group consisting of an anionic surfactant, a cationic surfactant, and an amphoteric surfactant. Among these, the composition according to the embodiment of the present invention preferably contains an anionic surfactant.

The ionic surfactant is a compound having a surfactant function by having a hydrophilic group and a hydrophobic group exhibiting ionic properties, and is different from the above-described quaternary ammonium salt in this respect.

The ionic surfactant often has a hydrocarbon group as a hydrophobic group, and more specifically, often has an aliphatic hydrocarbon group (preferably a linear alkyl group or a branched alkyl group), an aromatic hydrocarbon group, or a hydrophobic group selected from a combination thereof.

In a case where the ionic surfactant has a hydrocarbon group, the hydrocarbon group preferably has 3 or more carbon atoms, more preferably 8 or more carbon atoms, and still more preferably 12 or more carbon atoms. The upper limit of the number of carbon atoms in these alkyl groups is not particularly limited, and is preferably 20 or less.

The molecular weight of the ionic surfactant is preferably 100 to 1,000 and more preferably 100 to 500.

### <Anionic Surfactant>

Examples of the anionic surfactant include a sulfonic acid-based surfactant, a phosphoric acid ester-based surfactant, a phosphonic acid-based surfactant, and a carboxylic acid-based surfactant. Among these, the anionic surfactant preferably has at least one of a sulfonic acid group or a phosphoric acid group as the hydrophilic group, and more preferably has a sulfonic acid group.

The anionic surfactant preferably has a group (an aralkyl group) in which one hydrogen atom in a linear or branched alkyl group or an aryl group (more preferably a phenyl group) is substituted with the linear or branched alkyl group.

The number of carbon atoms in the linear or branched alkyl group and the linear or branched alkyl group in the aralkyl group is preferably 3 to 25, more preferably 8 to 20, and still more preferably 12 to 18.

In addition, it is also preferable that the anionic surfactant has a cyclic structure. Examples of the cyclic structure include an aromatic ring, and among these, a benzene ring or a naphthalene ring is preferable.

### (Sulfonic Acid-Based Surfactant)

The sulfonic acid-based surfactant is a surfactant including, among a hydrophobic group and a hydrophilic group of the surfactant molecule, a sulfonic acid group in the hydrophilic group.

The hydrophobic group in the sulfonic acid-based surfactant is not particularly limited, and examples thereof include an aliphatic hydrocarbon group, an aromatic hydrocarbon group, and a combination of these groups. The number of carbon atoms in the hydrophobic group is preferably 6 or more and more preferably 10 or more. The upper limit of the number of carbon atoms in the hydrophobic group is not particularly limited, and is preferably 24 or less and more preferably 20 or less.

Examples of the sulfonic acid-based surfactant include an alkyl sulfonic acid-based surfactant, an alkyl aryl sulfonic acid-based surfactant (for example, alkylbenzene sulfonic acid and alkylnaphthalene sulfonic acid), an alkyldiphenyl ether disulfonic acid-based surfactant, a polyoxyalkylene alkyl ether sulfonic acid-based surfactant, a polyoxyethylene alkyl sulfate ester-based surfactant, and salts thereof.

Examples of the salt of the sulfonic acid-based surfactant include a sodium salt, a potassium salt, an ammonium salt, and an organic amine salt.

Specific examples of the sulfonic acid-based surfactant include hexane sulfonic acid, octane sulfonic acid, decane sulfonic acid, dodecyl sulfonic acid, toluene sulfonic acid, cumene sulfonic acid, (para) octylbenzene sulfonic acid, dodecylbenzene sulfonic acid ((S) DBS), branched dodecylbenzene sulfonic acid, monoisopropylnaphthalene sulfonic acid, dioctylsulfosuccinate, naphthalene sulfonic acid dinitrobenzene sulfonic acid (DNBSA), lauryldodecylphenylether disulfonic acid (LDPEDSA), and salts thereof.

The structures of the monoisopropylnaphthalenesulfonic acid and the dioctylsulfosuccinate are as follows.

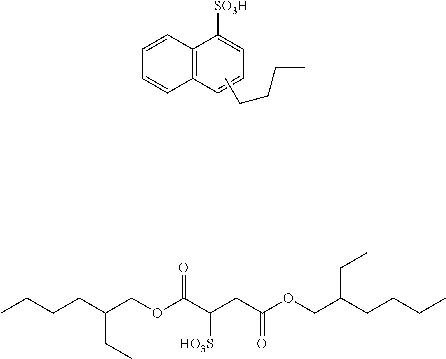

Among these, an alkyl aryl sulfonic acid-based surfactant is preferable as the sulfonic acid-based surfactant. That is, a sulfonic acid-based surfactant in which the surfactant molecule has an alkyl group and a sulfonic acid group and the surfactant molecule includes an aromatic hydrocarbon ring in the molecule is preferable.

The alkyl group included in the alkyl aryl sulfonic acid-based surfactant may be linear or branched, and is preferably branched. The number of carbon atoms in the above-described alkyl group is preferably 8 or more, more preferably 8 to 20, and still more preferably 10 to 13.

Examples of the aromatic hydrocarbon ring included in the alkyl aryl sulfonic acid-based surfactant include a benzene ring and a naphthalene ring.

The sulfonic acid group included in the alkyl aryl sulfonic acid-based surfactant is preferably directly bonded to the aromatic hydrocarbon ring. The sulfonic acid group may form a salt with a cation.

As the alkyl aryl sulfonic acid-based surfactant, a surfactant represented by Formula (A) is preferable.

R^{a}—Ar^{a}—SO₃H (A)

In Formula (A), R^{a} represents an alkyl group having 8 or more carbon atoms. Ar^{a} represents an arylene group.

The suitable aspect of the alkyl group is as described above.

The above-described arylene group may be monocyclic or polycyclic. The number of carbon atoms in the arylene group is preferably 6 to 20 and more preferably 6 to 15.

As the arylene group, a phenylene group or a naphthylene group is preferable.

Among these, an alkylbenzene sulfonic acid-based surfactant such as DBS is preferable as the alkyl aryl sulfonic acid-based surfactant. That is, a sulfonic acid-based surfactant in which the surfactant molecule has an alkyl group and a sulfonic acid group and the surfactant molecule includes at least one benzene ring in the molecule is preferable. Hereinafter, the alkylbenzene sulfonic acid-based surfactant is also referred to as “ABS”.

The alkyl group contained in the ABS is preferably linear or branched and more preferably branched. The number of carbon atoms in the alkyl group included in the ABS is preferably 8 or more, more preferably 8 to 20, and still more preferably 10 to 13.

Examples of the ABS include aspects in which Ar^{a} in Formula (A) is a phenylene group.

Examples of the ABS include octylbenzene sulfonic acid, nonylbenzene sulfonic acid, decylbenzene sulfonic acid, undecylbenzene sulfonic acid, dodecylbenzene sulfonic acid, tridecylbenzene sulfonic acid, tetradecylbenzene sulfonic acid, pentadecylbenzene sulfonic acid, hexadecanebenzene sulfonic acid, heptadecanebenzene sulfonic acid, octadecanebenzene sulfonic acid, nonadecanbenzene sulfonic acid, eicosylbenzene sulfonic acid, decyldiphenyloxide disulfonic acid, undecyldiphenyloxide disulfonic acid, dodecyldiphenyloxide disulfonic acid, and tridecyldiphenyloxide disulfonic acid; sodium salts of these acids, potassium salts of these acids, and ammonium salts of these acids.

The alkyl group in the above-described ABS is preferably linear or branched and more preferably branched.

In addition, in a case where the alkyl group is branched, a bonding position of the alkyl group with the benzene ring is not particularly limited.

It is also preferable that the above-described sulfonic acid-based surfactant includes an alkylbenzene sulfonic acid-based surfactant 1 including an alkyl group having 10 carbon atoms (hereinafter, also referred to as “ABS1”), an alkylbenzene sulfonic acid-based surfactant 2 including an alkyl group having 11 carbon atoms (hereinafter, also referred to as “ABS2”), an alkylbenzene sulfonic acid-based surfactant 3 including an alkyl group having 12 carbon atoms (hereinafter, also referred to as “ABS3”), and an alkylbenzene sulfonic acid-based surfactant 4 including an alkyl group having 13 carbon atoms (hereinafter, also referred to as “ABS4”).

Examples of the ABS1 include aspects in which, in Formula (A), Ar^{a} is a phenylene group and R^{a} is an alkyl group having 10 carbon atoms. Examples of the ABS2 include aspects in which, in Formula (A), Ar^{a} is a phenylene group and Ra is an alkyl group having 11 carbon atoms. Examples of the ABS3 include aspects in which, in Formula (A), Ar^{a} is a phenylene group and R^{a} is an alkyl group having 12 carbon atoms. Examples of the ABS4 include aspects in which, in Formula (A), Ar^{a} is a phenylene group and R^{a} is an alkyl group having 13 carbon atoms.

A content of the ABS1 with respect to the total mass of ABS's 1 to 4 is not particularly limited, but is preferably 5% to 50% by mass. A content of the ABS2 with respect to the total mass of ABS's 1 to 4 is not particularly limited, but is preferably 20% to 50% by mass. A content of the ABS3 with respect to the total mass of ABS's 1 to 4 is not particularly limited, but is preferably 20% to 50% by mass. A content of the ABS4 with respect to the total mass of ABS's 1 to 4 is not particularly limited, but is preferably 20% to 50% by mass.

### (Phosphoric Acid Ester-Based Surfactant)

Examples of the phosphoric acid ester-based surfactant include phosphoric acid ester (alkyl phosphoric acid ester and aryl phosphoric acid ester), mono-or polyoxyalkylene ether phosphoric acid ester (mono-or polyoxyalkylene alkyl ether phosphoric acid ester and mono- or polyoxyalkylene aryl ether phosphoric acid ester), and salts thereof.

Among these, at least one selected from the group consisting of alkyl phosphoric acid ester, mono- or polyoxyalkylene alkyl ether phosphoric acid ester, and salts thereof is preferable.

Examples of the salt of the phosphoric acid ester-based surfactant include a sodium salt, a potassium salt, an ammonium salt, and an organic amine salt.

The monovalent alkyl group contained in the alkyl phosphoric acid ester and the mono- or polyoxyalkylene alkyl ether phosphoric acid ester include an alkyl group having 6 to 22 carbon atoms, where an n alkyl group having 10 to 20 carbon atoms is preferable.

Examples of the monovalent aryl group contained in the aryl phosphoric acid ester and the mono- or polyoxyalkylene aryl ether phosphoric acid ester include an aryl group having 6 to 14 carbon atoms, which may have an alkyl group, where a phenyl group which may have an alkyl group is preferable.

Examples of the divalent alkylene group contained in the mono- or polyoxyalkylene alkyl ether phosphoric ester and the mono- or polyoxyalkylene aryl ether phosphoric ester include an alkylene group having 2 to 6 carbon atoms, and an ethylene group or a propylene group is preferable and an ethylene group is more preferable. The number of repeating units of the oxyalkylene group is preferably 1 to 12 and more preferably 1 to 10.

More specific examples of the phosphoric acid ester-based surfactant include octyl phosphoric acid ester, lauryl phosphoric acid ester, tridecyl phosphoric acid ester, myristyl phosphoric acid ester, cetyl phosphoric acid ester, stearyl phosphoric acid ester, mono- or polyoxyethylene octyl ether phosphoric acid ester, mono- or polyoxyethylene lauryl ether phosphoric acid ester, mono- or polyoxyethylene tridecyl ether phosphoric acid ester, and salts thereof.

In addition, as the phosphoric acid ester-based surfactant, the compounds described in

paragraphs to of JP2011-040502A, the contents of which can be incorporated in the present specification by reference, can also be used.

### <Cationic Surfactant>

The ionic surfactant may be a cationic surfactant.

The cationic surfactant preferably has a benzyl group or a linear or branched alkyl group as the hydrophobic group, and more preferably has a benzyl group or a linear alkyl group having 11 to 20 carbon atoms.

Examples of the cationic surfactant include primary to tertiary alkylamine salts (for example, monostearylammonium chloride, distearylammonium chloride, and tristearylammonium chloride), quaternary ammonium salts (for example, lauryltrimethylammonium chloride and lauryldimethylbenzylammonium chloride), and modified aliphatic polyamines (for example, polyethylene polyamine).

### <Amphoteric Surfactant>

The ionic surfactant may be an amphoteric surfactant.

Examples of the amphoteric surfactant include carboxybetaine (for example, alkyl-N,N-dimethylaminoacetic acid betaine, alkyl polyaminoethyl glycine hydrochloride, lauryl betaine, and alkyl-N,N-dihydroxyethylaminoacetic acid betaine), sulfobetaine (for example, alkyl-N,N-dimethylsulfoethyleneammonium betaine), alkylamine oxide (for example, lauryl dimethylamine oxide), and imidazolinium betaine (for example, 2-alkyl-N-carboxymethyl-N-hydroxyethyl imidazolinium betaine).

The content of the ionic surfactant is preferably 1 to 15,000 ppm by mass, more preferably 1 to 10,000 ppm by mass, still more preferably 10 to 5,000 ppm by mass, and particularly preferably 100 to 1,000 ppm by mass, with respect to the total mass of the composition.

### Nonionic Surfactant

The composition according to the embodiment of the present invention contains a nonionic surfactant.

The nonionic surfactant is a compound having a surfactant function by having a hydrophilic group and a hydrophobic group that do not exhibit ionic properties, unlike the ionic surfactant.

Examples of the hydrophilic group include a polyoxyalkylene chain. The nonionic surfactant preferably has a polyoxyalkylene chain composed of an oxyalkylene group selected from the group consisting of an oxyethylene group and an oxypropylene group as the hydrophilic group, and more preferably has a polyoxyethylene chain or a polyoxypropylene chain.

The oxyethylene group is a group represented by —CH₂—CH₂—O—, and examples of the polyoxypropylene group include a group represented by —CH₂—CH(CH₃)—O—.

The number of repeating units of the oxyalkylene group (-alkylene group-O—) in the polyoxyalkylene chain is preferably 3 to 50, more preferably 4 to 30, and still more preferably 6 to 20.

In addition, examples of the hydrophobic group include a monovalent hydrocarbon group.

The monovalent hydrocarbon group is preferably a monovalent aliphatic hydrocarbon group or an aryl group which may have a substituent, and more preferably a linear or branched alkyl group or an aryl group having a linear or branched alkyl group.

Among these, the nonionic surfactant preferably has a monovalent hydrocarbon group having 10 to 18 carbon atoms, and more preferably has a monovalent hydrocarbon group having 12 to 18 carbon atoms, as the hydrophobic group.

Examples of the nonionic surfactant include polyoxyalkylene alkyl ether (for example, polyoxyethylene alkyl ether and polyoxyethylene polyoxypropylene alkyl ether), polyoxyalkylene alkyl aryl ether (for example, polyoxyethylene alkyl phenyl ether), polyoxyethylene polystyryl phenyl ether, fatty acid ester (for example, glycerin fatty acid ester, sorbitan fatty acid ester, pentaerythritol fatty acid ester, propylene glycol monofatty acid ester, sucrose fatty acid ester, polyoxyethylene sorbitan fatty acid ester, polyoxyethylene sorbitol fatty acid ester, polyethylene glycol fatty acid ester, polyglycerin fatty acid ester, polyoxyethylene glycerin fatty acid ester, and triethanolamine fatty acid ester), polyoxyethylated castor oil-based fatty compound, acid diethanolamide, N,N-bis-2-hydroxyalkylamine, polyoxyethylene alkylamine, trialkylamine oxide, acetylene glycol, polyethylene glycol, and a copolymer of polyethylene glycol and polypropylene glycol.

The fatty acid ester may be a fatty acid partial ester in which a part of the fatty acid is esterified.

Among these, a polyoxyalkylene alkyl ether, a polyoxyalkylene alkyl aryl ether, or a fatty acid ester is preferable as the nonionic surfactant.

As the polyoxyalkylene alkyl ether, a compound represented by General Formula (b) is preferable.

R-L¹-(L²O)ₙ—H General Formula (b)

In General Formula (b), R represents an alkyl group.

L¹ represents a single bond, an oxygen atom, or an alkylene group which may have an oxygen atom.

L² represents an alkylene group having 2 or 3 carbon atoms, and a plurality of L²'s may be the same as or different from each other.

n represents a number of 2 or more.

In General Formula (b), the number of carbon atoms in the alkyl group represented by R is preferably 5 to 25, more preferably 8 to 20, and still more preferably 10 to 18. The alkyl group may be linear or branched.

The number of carbon atoms in the alkylene group which may have an oxygen atom, represented by L¹, is preferably 1 to 20, more preferably 1 to 10, and still more preferably 1 to 5.

n is preferably 3 to 50, more preferably 4 to 30, and still more preferably 6 to 20.

Examples of the alkylene group which may have an oxygen atom include —O—CH₂—CH₂— and —O—CH₂—CH₂—CH₂—.

As the polyoxyalkylene alkyl aryl ether, a compound represented by General Formula (c) is preferable.

R^{a}—Ar-L^{1a}(L^{2a}O)ₘ—H General Formula (c)

In General Formula (c), R^{a} represents an alkyl group.

Ar represents an arylene group.

L^{1a} represents a single bond, an oxygen atom, or an alkylene group which may have an oxygen atom.

L^{2a} represents an alkylene group having 2 or 3 carbon atoms, and a plurality of L^{2a}'s may be the same as or different from each other.

m represents a number of 2 or more.

In General Formula (c), a suitable aspect of Ra is the same as the suitable aspect of R.

As the arylene group represented by Ar, a phenylene group is preferable.

The suitable aspect of the alkylene group which may have an oxygen atom, represented by L^{1a}, is the same as the suitable aspect of L¹ described above.

m is preferably 3 to 50, more preferably 4 to 30, and still more preferably 6 to 20.

The HLB (hydrophile-lipophile balance) value of the nonionic surfactant is preferably 9.0 to 20.0 and more preferably 11.0 to 18.0.

Here, the HLB value is defined with a value calculated from the Griffin formula (20×Mw/M; Mw=Molecular weight of hydrophilic site, M=Molecular weight of nonionic surfactant), and in some cases, a catalog value or a value calculated by another method may be use.

As the HLB value is closer to 20, it is more hydrophilic, and as the HLB value is closer to 0, it is more lipophilic.

The content of the nonionic surfactant is preferably 1 to 15,000 ppm by mass, more preferably 1 to 10,000 ppm by mass, still more preferably 10 to 5,000 ppm by mass, and particularly preferably 100 to 1,000 ppm by mass, with respect to the total mass of the composition.

In addition, the mass ratio of the content of the nonionic surfactant to the content of the ionic surfactant is preferably 0.1 to 100 and more preferably 1 to 10.

### Optional Component

The composition may contain optional components in addition to the components described above.

Hereinafter, the optional components that may be contained in the composition will be described in detail.

### (Solvent)

The composition according to the embodiment of the present invention may contain a solvent.

Examples of the solvent include water and an organic solvent, and water is preferable.

The water is preferably water that has been subjected to a purification treatment, such as distilled water, ion exchange water, and ultrapure water, and more preferably ultrapure water used for producing semiconductors. Water to be incorporated into the composition may contain a trace of components that are unavoidably mixed in.

The content of water with respect to the total mass of the composition is preferably 50% by mass or more, more preferably 65% by mass or more, and still more preferably 75% by mass or more. The upper limit thereof is not particularly limited. The upper limit with respect to the total mass of the composition is preferably 99.999% by mass or less, and more preferably 99.9% by mass or less.

As the organic solvent, a water-soluble organic solvent is preferable. The water-soluble organic solvent refers to an organic solvent that can be mixed with water at an arbitrary ratio.

Examples of the water-soluble organic solvent include an ether-based solvent, an alcohol-based solvent, a ketone-based solvent, an amide-based solvent, a sulfur-containing solvent, and a lactone-based solvent.

Examples of the ether-based solvent include diethyl ether, diisopropyl ether, dibutyl ether, t-butyl methyl ether, cyclohexyl methyl ether, tetrahydrofuran, diethylene glycol, dipropylene glycol, triethylene glycol, polyethylene glycol, alkylene glycol monoalkyl ether (ethylene glycol monomethyl ether, ethylene glycol monobutyl ether, propylene glycol monomethyl ether, diethylene glycol monomethyl ether, dipropylene glycol monomethyl ether, tripropylene glycol monomethyl ether, and diethylene glycol monobutyl ether), alkylene glycol dialkyl ether (diethylene glycol diethyl ether, diethylene glycol dipropyl ether, diethylene glycol dibutyl ether, triethylene glycol diethyl ether, tetraethylene glycol dimethyl ether, tetraethylene glycol diethyl ether, ethylene glycol dimethyl ether, diethylene glycol dimethyl ether, and triethylene glycol dimethyl ether).

The number of carbon atoms in the ether-based solvent is preferably 3 to 16, more preferably 4 to 14, and still more preferably 6 to 12.

Examples of the alcohol-based solvent include methanol, ethanol, 1-propanol, 2-propanol, 1-butanol, 2-butanol, ethylene glycol, propylene glycol, glycerin, 1,6-hexanediol, cyclohexanediol, sorbitol, xylitol, 2-methyl-2,4-pentanediol, 1,3-butanediol, and 1,4-butanediol.

The number of carbon atoms in the alcohol-based solvent is preferably 1 to 8, and more preferably 1 to 4.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the ketone-based solvent include acetone, methyl ethyl ketone, methyl isobutyl ketone, and cyclohexanone.

Examples of the sulfur-containing solvent include dimethyl sulfone, dimethyl sulfoxide, and sulfolane.

Examples of the lactone-based solvent include γ-butyrolactone and δ-valerolactone.

One organic solvent may be used alone, or two or more organic solvents may be used in combination.

The content of the organic solvent is preferably 0.1% to 10% by mass with respect to the total mass of the composition.

In a case where two or more organic solvents are used, the total content of two or more organic solvents is also preferably within the above range.

### (Basic Compound)

The composition may contain a basic compound.

The basic compound is a compound that is alkaline (having a pH of more than 7.0) in an aqueous solution.

Examples of the basic compound include an organic base, an inorganic base, and salts thereof.

However, the basic compound does not include the above-described quaternary ammonium salt, ionic surfactant, and solvent.

Examples of the organic base include an amine compound, an alkanolamine compound and a salt thereof, an amine oxide compound, a nitro compound, a nitroso compound, an oxime compound, a ketoxime compound, an aldoxime compound, a lactam compound, and an isocyanide compound. Furthermore, the amine compound means a compound that has an amino group in the molecule, in which the compound is not included in the alkanolamine, amine oxide compound, and lactam compound.

However, the organic base does not include the above-described quaternary ammonium salt.

Examples of the inorganic base include alkali metal hydroxides such as sodium hydroxide and potassium hydroxide, alkaline earth metal hydroxides, and ammonia or a salt thereof.

The content of the basic compound is not particularly limited, and is preferably 0.1% by mass or more and more preferably 0.5% by mass or more with respect to the total mass of the composition. The upper limit of the content of the basic compound is not particularly limited, and is preferably 20.0% by mass or less with respect to the total mass of the composition.

It is also preferable to adjust the content of the basic compound within the above suitable range so that the pH of the composition falls into a suitable range which will be described later.

### (Acidic Compound)

The composition may contain an acidic compound.

The acidic compound is a compound that is acidic (having a pH of less than 7.0) in an aqueous solution.

However, the acidic compound does not include the above-described periodic acid or a salt thereof.

Examples of the acidic compound include an inorganic acid, an organic acid, and salts thereof.

Examples of the inorganic acid include sulfuric acid, hydrochloric acid, phosphoric acid, nitric acid, hydrofluoric acid, iodic acid, perchloric acid, hypochlorous acid, and salts thereof.

Examples of the organic acid include carboxylic acid, sulfonic acid, and salts thereof.

The content of the acidic compound is not particularly limited, and is preferably 0.1% by mass or more and more preferably 0.5% by mass or more with respect to the total mass of the composition. The upper limit of the content of the basic compound is not particularly limited, and is preferably 20.0% by mass or less with respect to the total mass of the composition.

It is also preferable to adjust the content of the acidic compound within the above suitable range so that the pH of the composition falls into a suitable range which will be described later.

### (Water-Soluble Polymer)

The composition according to the embodiment of the present invention may contain a water-soluble polymer. However, the compound included in the metal corrosion inhibitor described later is not included.

Examples of the water-soluble polymer include polyacrylic acid, polyvinyl alcohol, polyethylene glycol, polyethylene oxide, a carboxyvinyl polymer, and the like.

### (Metal Corrosion Inhibitor)

The composition may contain a metal corrosion inhibitor.

As the metal corrosion inhibitor, a metal corrosion inhibitor containing a nitrogen atom is preferable. Examples thereof include a chelating agent described in detail later.

### Chelating Agent

The chelating agent has at least two nitrogen-containing groups.

Examples of the nitrogen-containing group include a primary amino group, a secondary amino group, an imidazolyl group, a triazolyl group, a benzotriazolyl group, a piperazinyl group, a pyrrolyl group, a pyrrolidinyl group, a pyrazolyl group, a piperidinyl group, a guanidinyl group, a biguanidinyl group, a hydrazinocarbonyloxy group, a hydrazido group, a semicarbazido group, and an aminoguanidinyl group.

The chelating agent may have two or more nitrogen-containing groups, and the two or more nitrogen-containing groups may be different from each other, partially the same, or all the same.

In addition, the chelating agent may contain a carboxy group.

The nitrogen-containing group and/or the carboxy group contained in the chelating agent may be neutralized to form a salt.

As the chelating agent, the chelating agents described in paragraphs [0021] to [0047] of JP2017-504190A can be used, the contents of which are incorporated in the present specification.

One chelating agent may be used alone, or two or more chelating agents may be used in combination.

The content of the chelating agent with respect to the total mass of the composition is preferably 0.01% to 2% by mass, more preferably 0.1% to 1.5% by mass, and still more preferably 0.3% to 1.0% by mass.

### Other Metal Corrosion Inhibitors

The metal corrosion inhibitor may be benzotriazole which may have a substituent. Here, benzotriazole contained in the chelating agent is excluded.

Examples of the benzotriazole which may have a substituent include benzotriazole (BTA), 5-aminotetrazole, 1-hydroxybenzotriazole, 5-phenylthiol-benzotriazole, 5-chlorobenzotriazole, 4-chlorobenzotriazole, 5-bromobenzotriazole, 4-bromobenzotriazole, 5-fluorobenzotriazole, 4-fluorobenzotriazole, naphthotriazole, tolyltriazole, 5-phenyl-benzotriazole, 5-nitrobenzotriazole, 4-nitrobenzotriazole, 3-amino-5-mercapto-1,2,4-triazole, 2-(5-amino-pentyl)-benzotriazole, 1-amino-benzotriazole, 5-methyl-1H-benzotriazole, benzotriazole-5-carboxylic acid, 4-methylbenzotriazole, 4-ethylbenzotriazole, 5-ethylbenzotriazole, 4-propylbenzotriazole, 5-propylbenzotriazole, 4-isopropylbenzotriazole, 5-isopropylbenzotriazole, 4-n-butylbenzotriazole, 5-n-butylbenzotriazole, 4-isobutylbenzotriazole, 5-isobutylbenzotriazole, 4-pentylbenzotriazole, 5-pentylbenzotriazole, 4-hexylbenzotriazole, 5-hexylbenzotriazole, 5-methoxybenzotriazole, 5-hydroxybenzotriazole, dihydroxypropylbenzotriazole, 1-[N,N-bis(2-ethylhexyl)aminomethyl]-benzotriazole, 5-t-butylbenzotriazole, 5-(1′, 1′-dimethylpropyl)-benzotriazole, 5-(1′, 1′,3′-trimethylbutyl)benzotriazole, 5-n-octylbenzotriazole, and 5-(1′,1′,3′,3′-tetramethylbutyl)benzotriazole.

The content of the metal corrosion inhibitor is not particularly limited, but is preferably 0.1% by mass or more and more preferably 1% by mass or more with respect to the total mass of the composition. The upper limit of the content of the metal corrosion inhibitor is not particularly limited, and is preferably 10% by mass or less and more preferably 5% by mass or less with respect to the total mass of the composition.

### (Metal Component)

The composition may contain a metal component.

Examples of the metal component include metal particles and metal ions. For example, the content of the metal component means the total content of metal particles and metal ions. The composition may contain either metal particles or metal ions, or may contain both of them.

Examples of the metal atom contained in the metal component include metal atoms selected from the group consisting of Ag, Al, As, Au, Ba, Ca, Cd, Co, Cr, Cu, Fe, Ga, Ge, K, Li, Mg, Mn, Mo, Na, Ni, Pb, Sn, Sr, Ti, Zn, and Zr.

The metal component may contain one metal atom or two or more metal atoms.

The metal particles may be a simple substance or an alloy, and may be in the form in which a metal and an organic substance are aggregated.

The metal component may be a metal component which is inevitably incorporated into each component (raw material) of the composition or a metal component inevitably incorporated into the composition during the producing, storage, and/or transfer of the composition. Alternatively, the metal component may be intentionally added.

In a case where the composition contains a metal component, the content of the metal component is often 0.01 ppt by mass to 10 ppm by mass with respect to the total mass of the composition. The content of the metal component is preferably 0.1 ppt by mass to 1 ppm by mass, and more preferably 0.1 ppt by mass to 100 ppb by mass.

The type and content of the metal component in the composition can be measured by inductively coupled plasma mass spectrometry (inductively coupled plasma mass spectrometry: ICP-MS).

In the ICP-MS method, the content of the metal component to be measured is measured regardless of the existence form thereof. As a result, the total mass of metal particles to be measured and metal ions is quantified as the content of the metal component.

For the measurement by SP-ICP-MS, for example, it is possible to use Agilent 8800 triple quadrupole inductively coupled plasma mass spectrometry (ICP-MS, for semiconductor analysis, option #200) and Agilent 8900 manufactured by Agilent Technologies, Inc. and NexION 350S manufactured by PerkinElmer, Inc.

The method of adjusting the content of each metal component in the composition is not particularly limited. For example, by performing a known treatment of removing metals from the composition and/or from the raw material containing each component used for preparing the composition, it is possible to reduce the content of the metal component in the composition. In addition, the content of the metal component in the composition can be increased by adding a compound containing metal ions to the composition.

### Characteristics of Composition

Hereinafter, the chemical properties and the physical properties exhibited by the composition will be described.

[pH]

The pH of the composition according to the embodiment of the present invention is not particularly limited and is, for example, in a range of 1.0 to 14.0.

Among these, the pH of the composition is preferably 1.0 to 12.0, more preferably 3.0 to 10.0, and still more preferably 4.0 to 9.0.

In the present specification, the pH of the composition is a value obtained by measuring pH at 25° C. using a pH meter (F-51 (trade name), manufactured by Horiba, Ltd.).

### Coarse Particles

The composition may contain coarse particles, but it is preferable that a content thereof is low.

The coarse particles mean particles having a diameter (particle size) of 0.1 μm or more, in a case where a shape of the particles is regarded as a sphere.

It is preferable that the composition is substantially free of coarse particles. The fact that the composition does not substantially include coarse particles means that the content of the particles having a particle diameter of 0.1 μm or more is 10,000 or less, and it is preferably 5,000 or less, per 1 mL of the composition. The lower limit thereof is preferably 0 or more and more preferably 0.01 or more per 1 mL of the composition.

The coarse particles included in the composition correspond to particles of dust, dirt, organic solids, inorganic solids, or the like included as impurities in raw materials, and particles of dust, dirt, organic solids, inorganic solids, or the like brought in as contaminants during the preparation of the composition, which are present as insoluble particles without being finally dissolved in the composition.

The content of the coarse particles present in the composition can be measured in a liquid phase by using a commercially available measuring device in a light scattering type in-liquid particle measurement system using a laser as a light source.

Examples of a method for removing the coarse particles include a purification treatment such as filtering which will be described later.

### Method for Producing Composition

The producing method of the composition according to the embodiment of the present invention is not particularly limited. For example, by mixing together the components described above, the composition can be produced. The order or timing of mixing cach component and the order and timing of mixing each component are not particularly limited. For example, a method of sequentially adding an periodic acid or a salt thereof, a quaternary ammonium salt, an ionic surfactant, a nonionic surfactant, and optional components to a stirrer such as a mixer containing purified pure water, and then sufficiently stirring the components to mix the components and produce a composition can be used.

Examples of the method for producing the composition include a method of adjusting the pH of the cleaning liquid in advance using the basic compound or the acidic compound, and then mixing the respective components, and a method of adjusting the pH to a set value using the basic compound or the acidic compound after mixing the respective components.

Furthermore, the composition according to the embodiment of the present invention may be produced by a method of producing a concentrated solution having a lower content of a solvent, such as water, compared to the composition to be used, and diluting the solution with a diluent (preferably water) when the composition needs to be used such that the content of each component is adjusted to a predetermined content. The composition according to the embodiment of the present invention may be produced by diluting the concentrated solution with a diluent and then adjusting the pH to a set value using the basic compound or the acidic compound. In a case of diluting the concentrated solution, a predetermined amount of the diluent may be added to the concentrated solution or a predetermined amount of the concentrated solution may be added to the diluent.

### Metal Removal Step

In the above producing method, a metal removal step of removing a metal component from the aforementioned component and/or the composition (hereinafter, also called “substance to be purified”) may be performed. For example, an aspect in which the metal removal step is performed on a substance to be purified containing the periodic acid or a salt thereof and water is exemplified.

Examples of the metal removal step include a step P in which the substance to be purified is subjected to an ion exchange method.

### (Step P)

In the step P, the above-mentioned substance to be purified is subjected to an ion exchange method.

The ion exchange method is not particularly limited as long as it is a method capable of adjusting (reducing) the amount of metal components in the substance to be purified, but the ion exchange method preferably includes one or more of the following method P1 to method P3. The ion exchange method more preferably includes two or more of the methods P1 to P3, and still more preferably includes all of the methods P1 to P3. In a case where the ion exchange method includes all of the methods P1 to P3, the methods may be carried out in any order without particular limitation, but it is preferable to carry out the methods P1 to P3 in this order.

Method P1: a method of passing the substance to be purified through a first filling portion filled with a mixed resin including two or more resins selected from the group consisting of a cation exchange resin, an anion exchange resin, and a chelating resin. The first filling portion generally includes a container and a mixed resin including two or more resins selected from the group consisting of a cation exchange resin, an anion exchange resin, and a chelating resin, which are filled in the container.

Method P2: a method of passing the substance to be purified through at least one filling portion of a second filling portion filled with a cation exchange resin, a third filling portion filled with an anion exchange resin, or a fourth filling portion filled with a chelating resin. The second filling portion usually includes a container and the above-described cation exchange resin filled in the container, the third filling portion usually includes a container and the above-described anion exchange resin filled in the container, and the fourth filling portion usually includes a container and a chelating resin described below filled in the container.

Method P3: a method of passing the substance to be purified through a membrane-like ion exchanger.

Examples of the form of the ion exchange resin and the chelating resin used in the method include a granular form, a fibrous form, and a porous monolithic form, and a granular form or a fibrous form is preferable.

The average particle diameter of the granular ion exchange resin and chelating resin is preferably 10 to 2,000 μm and more preferably 100 to 1,000 μm.

As for the particle size distribution of the granular ion exchange resin and chelating resin, it is preferable that the abundance ratio of resin particles having a size in a range of average particle diameter ±200 μm is 90% or more.

The average particle diameter and the particle size distribution may be measured, for example, using a particle size distribution analyzer (Microtrac HRA3920, manufactured by Nikkiso Co., Ltd.) and using water as a dispersion medium.

### Filtration Step

The above-mentioned producing method preferably includes a filtration step of filtering a liquid in order to remove foreign substances, coarse particles, and the like from the liquid.

The filtration method is not particularly limited, and a publicly known filtration method can be used. Above all, filtering using a filter is preferable. In a case of using a filter, different filters may be combined.

The filter that is used for filtering can be used without particular limitation as long as it is a filter that is conventionally used in the use application of filtering. Examples of the material constituting the filter include a fluororesin such as polytetrafluoroethylene (PTFE), a polyamide-based resin such as nylon, a polyolefin-based resin (including a high density, ultrahigh-molecular-weight polyolefin-based resin) such as polyethylene or polypropylene (PP), and polyarylsulfone. Above all, a polyamide-based resin, PTFE, polypropylene (including high density polypropylene), and polyarylsulfone are preferable.

In a case of using a filter formed from these materials, it is possible to more effectively remove foreign substances having high polarity, which are likely to cause defects, from the composition.

The pore diameter of the filter is preferably about 0.001 to 1.0 μm, more preferably about 0.02 to 0.5 μm, and still more preferably about 0.01 to 0.1 μm. In a case of setting the pore diameter of the filter within the above range, it is possible to reliably remove fine foreign substances contained in the composition while suppressing filtration clogging.

In a case where filtering is performed, the upper limit value of the temperature during the filtering is preferably equal to or lower than room temperature (25° C.), more preferably 23° C. or lower, and still more preferably 20° C. or lower. The lower limit value of the temperature during the filtering is preferably 0° C. or higher, more preferably 5° C. or higher, and still more preferably 10° C. or higher.

By the filtering, particle-like foreign substances and/or impurities can be removed. In a case where the filtering is carried out at the above temperature, the amount of particle-like foreign substances and/or impurities dissolved in the composition is reduced, and thus the filtering is more efficiently performed.

### Static Neutralization Step

The method for producing a composition may further include a static neutralization step of statically neutralizing the composition.

### Container

For example, a known container can be used as the container for accommodating the composition.

It is preferable that the container has a high degree of cleanliness in the container for use in semiconductors and less elution of impurities.

Examples of the container include “CLEAN BOTTLE” series (manufactured by Aicello Corporation) and “PURE BOTTLE” (manufactured by Kodama Plastics Co., Ltd.). In addition, from the viewpoint of preventing the incorporation (contamination) of impurities into the raw materials and the composition, it is also preferable to use a multi-layer container in which an interior wall of the container has a six-layer structure consisting of six types of resins, or a multi-layer container in which an interior wall of the container has a seven-layer structure consisting of seven types of resins.

Examples of the multi-layer container include the containers described in JP2015-123351A, the contents of which are incorporated herein by reference.

It is preferable to wash the inside of the container before being filled with the composition.

The liquid used for washing can be appropriately selected depending on the intended use, and is preferably a liquid containing a composition or at least one of the components added to the composition.

The inside of the container may be purged with an inert gas (for example, nitrogen or argon) having a purity of 99.99995% by volume or more from the viewpoint of preventing changes in the components of the composition during the storage. In particular, a gas having a low moisture content is preferable. In addition, in a case where the container accommodating the composition is transported and stored, the transport and storage may be carried out at normal temperature or under temperature control. Above all, from the viewpoint of preventing deterioration, it is preferable to control the temperature in a range of −20° C. to 20° C.

### Method for Treating Object to be Treated

The composition according to the embodiment of the present invention can be applied to various uses, and in particular, can be suitably used for treating an object to be treated containing Ru.

Hereinafter, a method for treating an object to be treated (hereinafter, also simply referred to as an “object to be treated”) containing Ru, using the composition according to the embodiment of the present invention, will be described. First, the object to be treated will be described.

### Object to be Treated

The object to be treated contains ruthenium (Ru).

Ru in the object to be treated is preferably present on the substrate. In addition, Ru in the object to be treated may be present as a simple substance of Ru or may be present as a compound (including an alloy containing Ru) containing Ru and another atom.

Hereinafter, a simple substance of Ru and a compound containing Ru and another atom are collectively referred to as a Ru-containing substance. The Ru-containing substance is a component containing Ru.

In the present specification, “on a substrate” includes, for example, all of the front and back, the lateral surfaces, the inside of grooves of a substrate, and the like. The Ru-containing substance on a substrate includes not only a Ru-containing substance which is directly on the surface of the substrate but also a Ru-containing substance which is on the substrate via another layer.

Hereinafter, recess portions such as grooves and holes provided on the substrate will be also called “a groove or the like”.

In addition, the presence of the Ru-containing substance in the object to be treated means a state in which the Ru-containing substance and the composition can be brought into contact with each other in a case where the object to be treated is brought into contact with the composition. In addition, the state in which the Ru-containing substance can be in contact with the surface also includes not only an aspect in which the Ru-containing substance is exposed to the outside but also an aspect in which a member covering the Ru-containing substance is removed by some action and the Ru-containing substance can be exposed.

The type of substrate is not particularly limited, and is preferably a semiconductor substrate.

Examples of the substrate include a semiconductor wafer, a glass substrate for a photomask, a glass substrate for liquid crystal display, a glass substrate for plasma display, a substrate for field emission display (FED), a substrate for an optical disk, a substrate for a magnetic disk, and a substrate for a magneto-optical disk. Examples of materials constituting the semiconductor substrate include silicon, germanium, silicon germanium, a Group III-V compound such as GaAs, and a combination of these.

The use of the object to be treated having been treated with the composition according to the embodiment of the present invention is not particularly limited. For example, such an object to be treated may be used for dynamic random access memory (DRAM), ferroelectric random access memory (FRAM (registered trademark)), magnetoresistive random access memory (MRAM), and phase change random access memory (PRAM), or may be used for a logic circuit, a processor, and the like.

The Ru-containing substance is not particularly limited as long as it is a substance containing Ru (a Ru atom). Examples of the Ru-containing substance include simple Ru, a Ru-containing alloy, a Ru oxide, a Ru nitride, and a Ru oxynitride.

The Ru oxide, the Ru nitride, and the Ru oxynitride may be a composite oxide, a composite nitride, or a composite oxynitride containing Ru.

The content of Ru atoms in the Ru-containing substance with respect to the total mass of the Ru-containing substance is preferably 10% by mass or more, more preferably 30% by mass or more, still more preferably 50% by mass or more, and particularly preferably 90% by mass or more. The upper limit thereof is not particularly limited, and is preferably 100% by mass or less with respect to the total mass of the Ru-containing substance.

The Ru-containing substance may contain other transition metals.

Examples of the transition metals include Rh (rhodium), Ti (titanium), Ta (tantalum), Co (cobalt), Cr (chromium), Hf (hafnium), Os (osmium), Pt (platinum), Ni (nickel), Mn (manganese), Cu (copper), Zr (zirconium), Mo (molybdenum), La (lanthanum), and Ir (iridium).

The form of the Ru-containing substance on the substrate is not particularly limited, and may be arranged in, for example, any of a film shape, a wiring shape, a plate shape, a columnar shape, or a particle shape. However, the composition of the present invention can be preferably used for an object to be treated in a form in which Ru is disposed on an end part (bevel portion) on the substrate.

Examples of the substrate, on which the Ru-containing substance is disposed in the form of particles, include a substrate obtained by performing dry etching on a substrate on which a Ru-containing film is disposed such that particle-like Ru-containing substances are then attached to the substrate as residues as will be described later, a substrate obtained by performing a chemical mechanical polishing (CMP) treatment on the Ru-containing film such that particle-like Ru-containing substances are then attached to the substrate as residues as will be described later, and a substrate obtained by depositing a Ru-containing film on a substrate such that a particle-like Ru-containing substance is then attached to a region other than a region where a Ru-containing film is supposed to be formed.

The thickness of the Ru-containing film is not particularly limited and may be appropriately selected depending on the use. For example, the thickness of the Ru-containing film is preferably 200 nm or less, more preferably 100 nm or less, and still more preferably 50 nm or less. The lower limit thereof is not particularly limited, and is preferably 0.1 nm or more.

The Ru-containing film may be disposed only on one main surface of the substrate, may be disposed on both main surfaces of the substrate, or may be disposed on an end part of the substrate. Furthermore, the Ru-containing film may be disposed on the entire main surface of the substrate, or may be disposed on a portion of the main surface of the substrate.

The object to be treated may include various layers or structures as desired in addition to the Ru-containing substance. For example, one or more members selected from the group consisting of a metal wire, a gate electrode, a source electrode, a drain electrode, an insulating film, a ferromagnetic layer, and a non-magnetic layer may be disposed on the substrate.

The substrate may include an exposed integrated circuit structure. Examples of the integrated circuit structure include interconnection mechanisms such as a metal wire and a dielectric material. Examples of metals and alloys used for the interconnection mechanism include aluminum, a copper-aluminum alloy, copper, titanium, tantalum, cobalt, silicon, titanium nitride, tantalum nitride, and molybdenum. The substrate may include a layer of one or more materials selected from the group consisting of silicon oxide, silicon nitride, silicon carbide, and carbon-doped silicon oxide.

The size, thickness, shape, layer structure, and the like of the substrate are not particularly limited, and can be appropriately selected as desired.

### Method for Producing Object to Be Treated

The method for producing an object to be treated is not particularly limited, and a known production method can be used. For example, a Ru-containing film can be formed on a substrate by using a sputtering method, a chemical vapor deposition (CVD) method, a molecular beam epitaxy (MBE) method, or an atomic layer deposition (ALD) method.

In forming a Ru-containing film by using the above producing method, in a case where the substrate has a structure with irregularities, sometimes the Ru-containing film is formed on all surfaces of the structure.

Especially, in a case where the Ru-containing film is formed by a sputtering method, a CVD method, or the like, sometimes the Ru-containing film is also attached to the back surface of the substrate on which the Ru-containing film is disposed (the surface opposite to the side of the Ru-containing film).

Furthermore, a Ru-containing wiring line may be formed on a substrate by performing the aforementioned method via a predetermined mask.

In addition, a substrate on which a Ru-containing film and/or a Ru-containing wiring line is disposed may be subjected to a predetermined treatment and used as an object to be treated by the treatment method according to the embodiment of the present invention.

For example, the above-described substrate may be subjected to dry etching to produce a substrate having a dry etching residue containing Ru. In addition, the above-described substrate may be subjected to CMP to produce a substrate having a Ru-containing substance. Furthermore, by a sputtering method, a CVD method, a molecular beam epitaxy method, or an atomic layer deposition method, a Ru-containing film may be deposited on the region where a Ru-containing film is supposed to be formed on the substrate, such that a substrate having a Ru-containing substance attached to a region other than the region where a Ru-containing film is supposed to be formed is produced.

A method for treating an object to be treated containing Ru, using the composition according to the embodiment of the present invention, will be described, typically, a method for treating a substrate on which a Ru-containing substance is present. Hereinafter, the substrate on which the Ru-containing substance is present is also simply referred to as a “substrate to be treated”.

### Step A

The method for treating a substrate to be treated (hereinafter, also referred to as “the present treatment method”) includes a step A of bringing an object to be treated (particularly, a substrate on which a Ru-containing substance is disposed) containing Ru into contact with the composition of the embodiment of the present invention. By carrying out this step, Ru can be removed.

In addition, the substrate (substrate to be treated) on which the Ru-containing substance is disposed is as described above.

The method of bringing the object to be treated into contact with the composition of the embodiment of the present invention is not particularly limited, and examples thereof include a method of immersing the object to be treated in the composition placed in a tank, a method of spraying the composition onto the object to be treated, a method of flowing the composition onto the object to be treated, and a combination thereof. Among these, the method of immersing the object to be treated in the composition is preferable.

Furthermore, a mechanical stirring method may also be used in order to further enhance the washing ability of the composition.

Examples of the mechanical stirring method include a method of circulating the composition on an object to be treated, a method of irrigating an object to be treated with the composition or spraying the composition onto an object to be treated, and a method of locally stirring the composition in the vicinity of a substrate by irradiation with ultrasonic waves (for example, megasonic).

The treatment time of the step A can be appropriately adjusted. The treatment time (the contact time between the composition and the object to be treated) is not particularly limited, and is preferably 0.25 to 10 minutes, and more preferably 0.5 to 2 minutes.

The temperature of the composition during the treatment is not particularly limited, and is preferably 20° C. to 75° C., more preferably 20° C. to 60° C., still more preferably 40° C. to 65° C., and particularly preferably 50° C. to 65° C.

In the step A, a treatment of adding one or more selected from the group consisting of a solvent and a component of the composition to the composition may be carried out as necessary while measuring the concentration of one or more components contained in the composition. In a case where this treatment is performed, the concentration of components in the composition can be stably maintained in a predetermined range. As the solvent, water is preferable.

Specific examples of suitable aspects of the step A include a step Al of performing a recess etching treatment on a Ru-containing wiring line or Ru-containing liner disposed on a substrate by using the composition, a step A2 of removing a Ru-containing film at an outer edge portion (bevel portion) of a substrate, on which the Ru-containing film is disposed, by using the composition, a step A3 of removing a Ru-containing substance attached to a back surface of a substrate, on which a Ru-containing film is disposed, by using the composition, a step A4 of removing a Ru-containing substance on a substrate, which has undergone dry etching, by using the composition, a step A5 of removing a Ru-containing substance on a substrate, which has undergone a chemical mechanical polishing treatment, by using the composition, or a step A6 of removing a ruthenium-containing substance in a region other than a region where a ruthenium-containing film is supposed to be formed on a substrate by using the composition after a ruthenium-containing film is deposited on the region where a ruthenium-containing film is supposed to be formed on the substrate.

Hereinafter, the present treatment method used in each of the above treatments will be described.

### (Step A1)

Examples of the step A include a step A1 of performing recess etching treatment on a Ru-containing wiring line (wiring line containing Ru) and a Ru-containing liner (liner containing Ru) disposed on a substrate by using the composition.

Hereinafter, as an example of the object to be treated in the step A1, a substrate having a Ru-containing wiring line, and a substrate having a Ru-containing liner will be specifically described.

### <Substrate Having Ru-Containing Wiring Line>

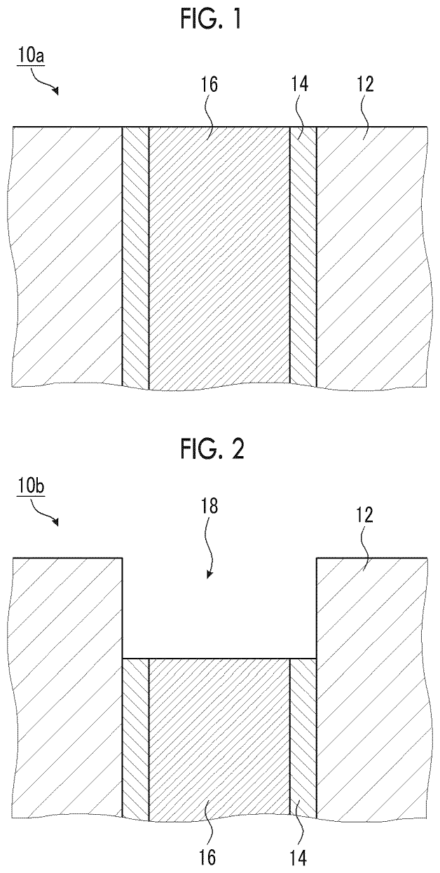

FIG. 1 is a schematic cross-sectional top view showing a substrate having a Ru-containing wiring line (hereinafter, also called “Ru wiring board”) which is an example of object to be treated by the recess etching treatment in the step A1.

A Ru wiring board 10a shown in FIG. 1 has a substrate not shown in the drawing, an insulating film 12 having a groove or the like disposed on the substrate, a barrier metal layer 14 disposed along the interior wall of the grooves or the like, and a Ru-containing wiring line 16 that fills up the inside of the grooves or the like.

The Ru-containing wiring line in the Ru wiring board preferably contains a simple substance of Ru or an alloy of Ru.

The material constituting the barrier metal layer in the Ru wiring board is not particularly limited, and examples thereof include a Ti metal, a Ti nitride, a Ti oxide, a Ti—Si alloy, a Ti—Si composite nitride, a Ti—Al alloy, a Ta metal, a Ta nitride, and a Ta oxide.

In FIG. 1, an aspect is illustrated in which the Ru wiring board has a barrier metal layer. However, the Ru wiring board may not have the barrier metal layer.

In the step A1, by performing a recess etching treatment on the Ru wiring board in the wiring board by using the aforementioned composition, a portion of the Ru-containing wiring line can be removed, and a recess portion can be formed.

More specifically, in a case where the step A1 is performed, as shown in a Ru wiring board 10b in FIG. 2, a portion of the barrier metal layer 14 and the Ru-containing wiring line 16 is removed, and a recess portion 18 is formed.

In the aspect shown in FIG. 2, the barrier metal layer 14 and the Ru-containing wiring line 16 are partially removed from the Ru wiring board 10b. However, the barrier metal layer 14 may not be removed, and only a part of the Ru-containing wiring line 16 may be removed to form the recess portion 18.

The producing method of the Ru wiring board is not particularly limited, and examples thereof include a method having a step of forming an insulating film on a substrate, a step of forming a groove or the like in the insulating film, a step of forming a barrier metal layer on the insulating film, a step of forming a Ru-containing film that fills up the grooves or the like, and a step of performing a smoothing treatment on the Ru-containing film.

### <Substrate Having Ru-Containing Liner>

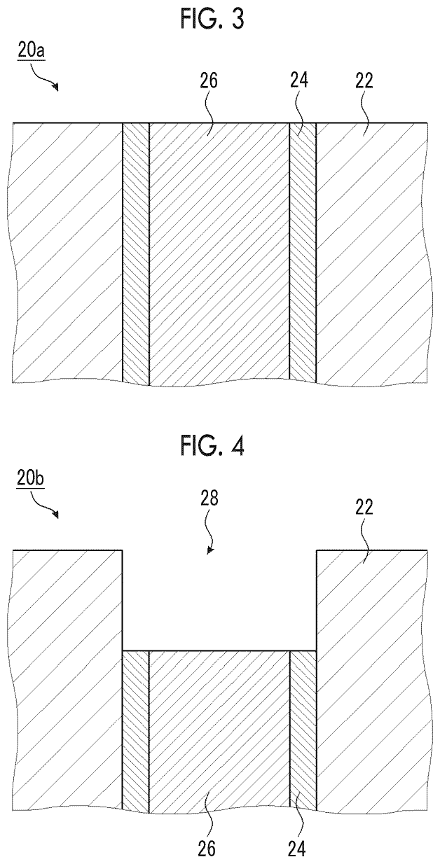

FIG. 3 is a schematic cross-sectional top view showing a substrate having a Ru-containing liner (hereinafter, also called “Ru liner substrate”) which is an example of an object to be treated by the recess etching treatment in the step A1.

A Ru liner substrate 20a shown in FIG. 3 has a substrate not shown in the drawing, an insulating film 22 having a groove or the like disposed on the substrate, a Ru-containing liner 24 disposed along the interior wall of the grooves or the like, and a wiring portion 26 that fills up the inside of the grooves or the like.

The Ru-containing liner in the Ru liner substrate preferably contains a simple substance of Ru or an alloy of Ru.

In the Ru liner substrate shown in FIG. 3, a barrier metal layer may be additionally provided between the Ru-containing liner 24 and the insulating film 22. Examples of the material constituting the barrier metal layer are the same as the material of the barrier metal layer in the Ru wiring board.

The material constituting the wiring portion in the Ru liner substrate is not particularly limited, and examples thereof include a Cu metal, a W metal, a Mo metal, and a Co metal.

In the step A1, by performing a recess etching treatment on the Ru liner substrate by using the aforementioned composition, a portion of the Ru-containing liner can be removed, and a recess portion can be formed.

More specifically, in a case where the step A1 is carried out, as shown in a Ru liner substrate 20b in FIG. 4, the Ru-containing liner 24 and the wiring portion 26 are partially removed to form a recess portion 28.

The producing method of the Ru liner substrate is not particularly limited, and examples thereof include a method having a step of forming an insulating film on a substrate, a step of forming a groove or the like in the insulating film, a step of forming a Ru liner on the insulating film, a step of forming a metal film that fills up the groove or the like, and a step of performing a smoothing treatment on the metal film.

Examples of specific methods of the step A1 include a method of bringing the Ru wiring board or the Ru liner substrate into contact with the composition.

The method of bringing the Ru wiring board or the Ru liner substrate into contact with the composition is as described above.

The suitable ranges of the contact time between the Ru wiring board or the Ru liner substrate and the composition and the temperature of the composition are as described above.

### (Step B)

Before or after the step A1, as necessary, a step B of treating the substrate obtained by the step A1 by using a predetermined solution (hereinafter, also called “specific solution”) may be performed.

Particularly, in a case where the barrier metal layer is disposed on the substrate, depending on the type of component constituting the Ru-containing wiring line or the Ru liner (hereinafter, also called “Ru-containing wiring line and the like”) and component constituting the barrier metal layer, sometimes these components exhibit different dissolving abilities to the composition according to the embodiment of the present invention. In this case, it is preferable to adjust the degree of solubility of the Ru-containing wiring line and the like and the barrier metal layer by using a solution that exhibits a higher dissolving ability to the barrier metal layer.

In this respect, as the specific solution, a solution is preferable which exhibits a poor dissolving ability to the Ru-containing wiring line and the like but exhibits an excellent dissolving ability to the substance constituting the barrier metal layer.

It is preferable that the specific solution has poor dissolving ability for the W-containing substance.

Examples of the specific solution include a solution selected from the group consisting of a mixed solution of hydrofluoric acid and hydrogen peroxide water (FPM), a mixed solution of sulfuric acid and hydrogen peroxide water (SPM), a mixed solution of aqueous ammonia and hydrogen peroxide water (APM), and a mixed solution of hydrochloric acid and hydrogen peroxide water (HPM).

The composition of FPM is, for example, preferably in a range of “hydrofluoric acid:hydrogen peroxide water:water=1:1:1” to “hydrofluoric acid:hydrogen peroxide water:water=1:1:200” (volume ratio).

The composition of SPM is, for example, preferably in a range of “sulfuric acid:hydrogen peroxide water:water=3:1:0” to “sulfuric acid: hydrogen peroxide water:water=1:1:10” (volume ratio).

The composition of APM is, for example, preferably in a range of “aqueous ammonia:hydrogen peroxide water:water=1:1:1” to “aqueous ammonia:hydrogen peroxide water:water=1:1:30” (volume ratio).

The composition of HPM is, for example, preferably in a range of “hydrochloric acid:hydrogen peroxide water:water=1:1:1” to “hydrochloric acid:hydrogen peroxide water:water=1:1:30” (volume ratio).

The preferred compositional ratio described above means a compositional ratio determined in a case where the hydrofluoric acid is 49% by mass hydrofluoric acid, the sulfuric acid is 98% by mass sulfuric acid, the aqueous ammonia is 28% by mass aqueous ammonia, the hydrochloric acid is 37% by mass hydrochloric acid, and the hydrogen peroxide water is 31% by mass hydrogen peroxide water.

In the step B, as the method of treating the substrate obtained by the step A1 by using the specific solution, a method of bringing the substrate obtained by the step A1 into contact with the specific solution is preferable.

The method of bringing the substrate obtained by the step A1 into contact with the specific solution is not particularly limited, and examples thereof include the same method as the method of bringing the substrate into contact with the composition.

The contact time between the specific solution and the substrate obtained by the step A1 is, for example, preferably 0.25 to 10 minutes, and more preferably 0.5 to 5 minutes.

In the present treatment method, the step A1 and the step B may be alternately repeated.

In a case where the steps are alternately repeated, it is preferable that each of the step A1 and the step B be performed 1 to 10 times. Furthermore, in a case where the step A1 and the step B are alternately repeated, the step performed firstly and the step performed lastly may be any of the step A1 or the step B.

### (Step A2)

Examples of the step A include a step A2 of removing a Ru-containing film at the outer edge portion of a substrate, on which the Ru-containing film is disposed, by using the composition.

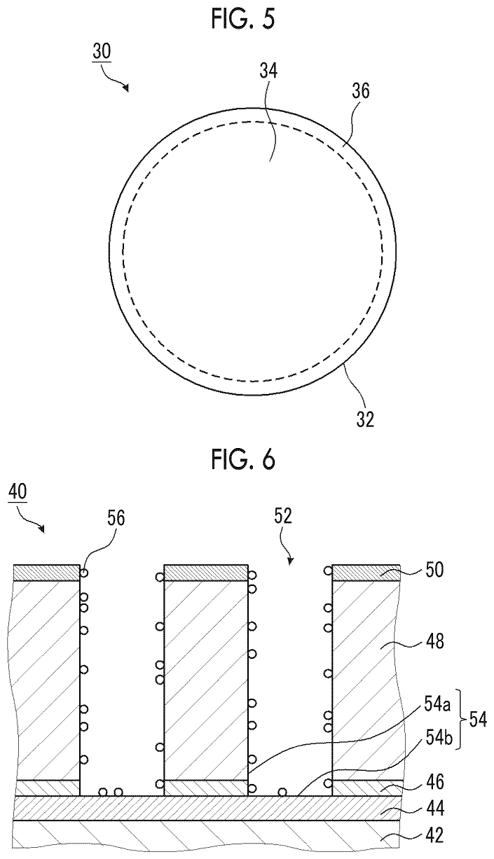

FIG. 5 is a schematic view (top view) showing an example of a substrate, on which a Ru-containing film is disposed, as an object to be treated by the step A2.

An object 30 to be treated by the step A2 shown in FIG. 5 is a laminate having a substrate 32 and a Ru-containing film 34 disposed on one main surface (entire region surrounded by the solid line) of the substrate 32. As will be described later, in step A2, the Ru-containing film 34 positioned at an outer edge portion 36 (the region outside the broken line) of the object 30 to be treated is removed.

The substrate in the object to be treated and the Ru-containing film are as described above.

The Ru-containing film preferably contains a simple substance of Ru or an alloy of Ru.

The specific method of the step A2 is not particularly limited, and examples thereof include a method of supplying the composition from a nozzle such that the composition comes into contact with only the Ru-containing film at the outer edge portion of the substrate.

At the time of performing the treatment of the step A2, it is possible to preferably use the substrate treatment device and the substrate treatment method described in JP2010-267690A, JP2008-080288A, JP2006-100368A, and JP2002-299305A.

The method of bringing the composition into contact with the object to be treated is as described above.

The suitable ranges of the contact time between the composition and the object to be treated and the temperature of the composition are as described above.

### (Step A3)

Examples of the step A include a step A3 of removing a Ru-containing substance attached to the back surface of a substrate, on which a Ru-containing film is disposed, by using the composition.

Examples of the object to be treated by the step A3 include the object to be treated used in the step A2. At the time of forming the object to be treated, which is composed of a substrate and a Ru-containing film disposed on one main surface of the substrate, used in the step A2, the Ru-containing film is formed by sputtering, CVD, or the like. At this time, sometimes a Ru-containing substance is attached to a surface (back surface) of the substrate that is opposite to the Ru-containing film. The step A3 is performed to remove such a Ru-containing substance in the object to be treated.

The specific method of the step A3 is not particularly limited, and examples thereof include a method of spraying the composition such that the composition comes into contact with only the back surface of the substrate.

The method of bringing the composition into contact with the object to be treated is as described above.

The suitable ranges of the contact time between the composition and the object to be treated and the temperature of the composition are as described above.

### (Step A4)

Examples of the step A include a step A4 of removing a Ru-containing substance on a substrate, which has undergone dry etching, by using the composition.

FIGS. 6 and 8 are a schematic view showing an example of the object to be treated by the step A4.

Hereinafter, each of drawing will be described.

An object 40 to be treated shown in FIG. 6 comprises a Ru-containing film 44, an etching stop layer 46, an interlayer insulating film 48, a metal hard mask 50 in this order on a substrate 42. Through a dry etching process or the like, a groove 52 or the like exposing the Ru-containing film 44 is formed at a predetermined position. That is, the object to be treated shown in FIG. 6 is a laminate which comprises the substrate 42, the Ru-containing film 44, the etching stop layer 46, the interlayer insulating film 48, and the metal hard mask 50 in this order and comprises the groove 52 or the like that extends from the surface of the metal hard mask 50 to the surface of the Ru-containing film 44 at the position of the opening portion of the metal hard mask 50. An interior wall 54 of the groove 52 or the like is composed of a cross-sectional wall 54a which includes the etching stop layer 46, the interlayer insulating film 48, and the metal hard mask 50, and a bottom wall 54b which consists of the exposed Ru-containing film 44. A dry etching residue 56 is attached to the interior wall 54 of the groove or the like.

The dry etching residue includes a Ru-containing substance.

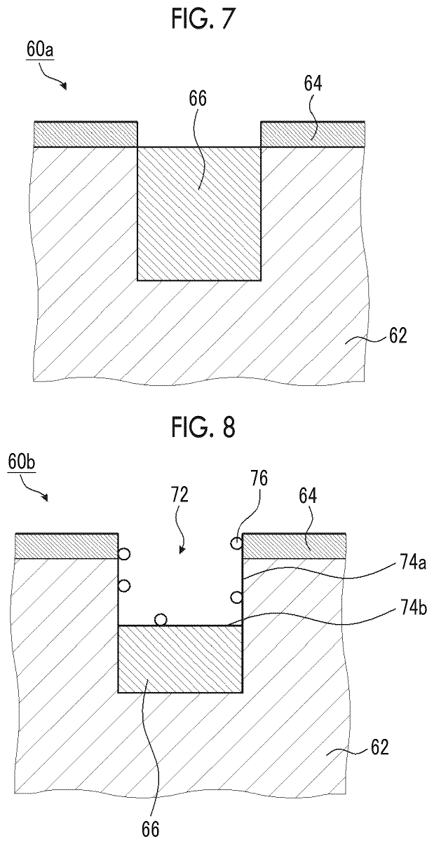

An object 60b to be treated shown in FIG. 8 is obtained by performing dry etching on an object to be treated not yet being subjected to dry etching shown in FIG. 7.

An object 60a to be treated shown in FIG. 7 has an insulating film 62 disposed on a substrate not shown in the drawing, a Ru-containing film 66 that fills up the groove or the like formed on the insulating film 62, and a metal hard mask 64 that has an opening portion where the Ru-containing film 66 is positioned, the opening portion being disposed on the insulating film 62. The object 60a to be treated is obtained by forming the insulating film 62 and the metal hard mask 64 in this order on a substrate not shown in the drawing, forming a groove or the like in the insulating film 62 positioned at the opening portion of the metal hard mask 64, and then filling the grooves or the like with a Ru-containing substance to form the Ru-containing film 66.

In a case where dry etching is performed on the object 60a to be treated shown in FIG. 7, the Ru-containing film is etched, and the object 60b to be treated shown in FIG. 8 is obtained.

The object 60b to be treated shown in FIG. 8 has the insulating film 62 disposed on a substrate not shown in the drawing, the Ru-containing film 66 that fills up a part of a groove 72 or the like formed in the insulating film 62, and metal hard mask 64 that has an opening portion positioned as the groove 72 or the like disposed on the insulating film 62. A dry etching residue 76 is attached to a cross-sectional wall 74a that consists of the insulating film 62 and the metal hard mask 64 in the groove 72 or the like and a bottom wall 74b that consists of the Ru-containing film 66.

The dry etching residue includes a Ru-containing substance.

The Ru-containing film of the object to be treated, which is subjected to the step A4, preferably contains a simple substance of Ru or an alloy of Ru.

The Ru-containing substance of the object to be treated, which is subjected to the step A4, preferably contains a simple substance of Ru or an alloy of Ru.

A known material is selected for the interlayer insulating film and the insulating film.

A known material is selected for the metal hard mask.

Although FIGS. 6, 7, and 8 describe an aspect in which a metal hard mask is used, a resist mask formed of a known photoresist material may also be used.

Examples of the specific method of the step A4 include a method of bringing the object to be treated into contact with the composition.

The method of bringing the composition into contact with the wiring board is as described above.

The suitable ranges of the contact time between the composition and the wiring board and the temperature of the composition are as described above.

### Step A5

Examples of the step A include a step A5 of removing a Ru-containing substance on a substrate, which has undergone a chemical mechanical polishing (CMP) treatment, by using the composition.

The CMP technique is used for smoothing an insulating film, smoothing connection holes, and a step of manufacturing damascene wiring line and the like. In some cases, a substrate having undergone CMP is contaminated with a large amount of particles used as abrasive particles, metal impurities, and the like. Therefore, it is necessary to remove these contaminants and wash the substrate before the next processing stage starts. By performing the step A5, it is possible to remove a Ru-containing substance which is generated in a case where the object to be treated by CMP includes a Ru-containing wiring line or a Ru-containing film and attached onto the substrate.

As described above, examples of the object to be treated by the step A5 include a substrate having undergone CMP that has a Ru-containing substance.

The Ru-containing substance preferably contains a simple substance of Ru or an alloy of Ru.

Examples of the specific method of the step A5 include a method of bringing the object to be treated into contact with the composition.

The method of bringing the composition into contact with the wiring board is as described above.

The suitable ranges of the contact time between the composition and the wiring board and the temperature of the composition are as described above.

### Step A6

Examples of the step A include a step A6 of removing a Ru-containing substance in a region other than a region where a Ru-containing film is supposed to be formed on a substrate by using the composition after a Ru-containing film is deposited on the region where a Ru-containing film is supposed to be formed on the substrate. As described above, the method of forming the Ru-containing film is not particularly limited, and the Ru-containing film can be formed on the substrate by using a sputtering method, a CVD method, an MBE method, and an ALD method.

In a case where a Ru-containing film is formed in a region where a Ru-containing film is supposed to be formed (a region where a Ru-containing film is supposed to be formed) on a substrate by the above method, the Ru-containing film is also formed in a non-target site (a region other than the region where a Ru-containing film is supposed to be formed). Examples of the non-target site include a side wall of the insulating film formed by the filling of the groove or the like provided in the insulating film with the Ru-containing film.

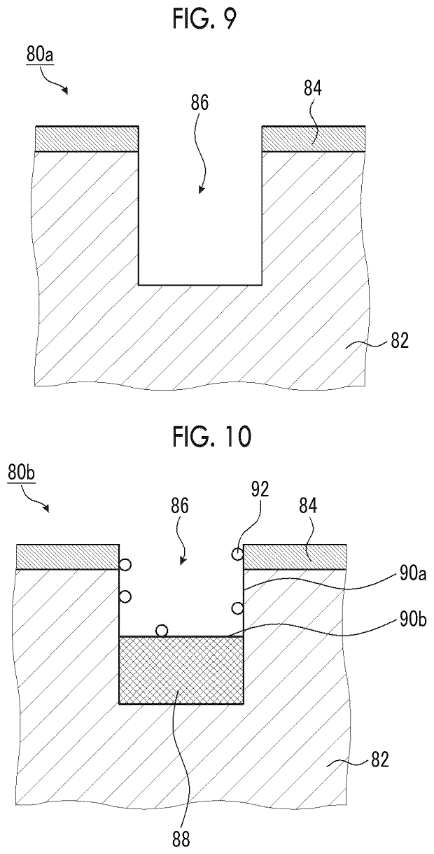

FIG. 10 shows an example of an object to be treated by the step A6. An object 80b to be treated shown in FIG. 10 is obtained by forming a Ru-containing film on an object 80a to be treated in which a Ru-containing film shown in FIG. 9 is not yet formed.

An object 80a to be treated shown in FIG. 9 has an insulating film 82 disposed on a substrate not shown in the drawing and a metal hard mask 84 disposed on the insulating film 82, and the insulating film 82 has a groove 86 or the like positioned at an opening portion of the metal hard mask 84. Forming an Ru-containing film to fill up a part of the groove 86 or the like of the object 80a to be treated makes it possible to obtain the object 80b to be treated described in FIG. 10.

The object 80b to be treated shown in FIG. 10 has the insulating film 82 disposed on a substrate not shown in the drawing, a Ru-containing film 88 that fills up a part of the groove 86 or the like formed in the insulating film 82, and the metal hard mask 84 that has an opening portion positioned at the groove 86 or the like disposed on the insulating film 82. A residue 92 generated during the formation of a Ru-containing film is attached to a cross-sectional wall 90a that consists of the insulating film 82 and the metal hard mask 84 in the groove 86 or the like and a bottom wall 90b that consists of the Ru-containing film 88.

In the above aspect, the region where the Ru-containing film 88 is positioned corresponds to the region where a Ru-containing film is supposed to be formed, and the cross-sectional wall 90a and the bottom wall 90b correspond to a region other than the region where a Ru-containing film is supposed to be formed.

The Ru-containing film preferably contains a simple substance of Ru or an alloy of Ru.

The Ru-containing substance preferably contains a simple substance of Ru or an alloy of Ru.

A known material is selected for the metal hard mask.

Although FIGS. 9 and 10 describe an aspect in which a metal hard mask is used, a resist mask formed of a known photoresist material may also be used.

Examples of the specific method of the step A6 include a method of bringing the object to be treated into contact with the composition.

The method of bringing the composition into contact with the wiring board is as described above.

The suitable ranges of the contact time between the composition and the wiring board and the temperature of the composition are as described above.

### Step C

As necessary, the present treatment step may have a step C of performing a rinsing treatment on the substrate obtained by the step A by using a rinsing liquid after the step A.

As the rinsing liquid, for example, hydrofluoric acid (preferably 0.001% to 1% by mass hydrofluoric acid), hydrochloric acid (preferably 0.001% to 1% by mass hydrochloric acid), hydrogen peroxide water (preferably 0.5% to 31% by mass hydrogen peroxide water, and more preferably 3% to 15% by mass hydrogen peroxide water), a mixed solution of hydrofluoric acid and hydrogen peroxide water (FPM), a mixed solution of sulfuric acid and hydrogen peroxide water (SPM), a mixed solution of aqueous ammonia and hydrogen peroxide water (APM), a mixed solution of hydrochloric acid and hydrogen peroxide water (HPM), aqueous carbon dioxide (preferably 10 to 60 ppm by mass aqueous carbon dioxide), aqueous ozone (preferably 10 to 60 ppm by mass aqueous ozone), aqueous hydrogen (preferably 10 to 20 ppm by mass aqueous hydrogen), an aqueous citric acid solution (preferably a 0.01% to 10% by mass aqueous citric acid solution), acetic acid (preferably an undiluted acetic acid solution or a 0.01% to 10% by mass aqueous acetic acid solution), sulfuric acid (preferably a 1% to 10% by mass aqueous sulfuric acid solution), aqueous ammonia (preferably 0.01% to 10% by mass aqueous ammonia), isopropyl alcohol (IPA), an aqueous hypochlorous acid solution (preferably a 1% to 10% by mass aqueous hypochlorous acid solution), aqua regia preferably aqua regia obtained by mixing together 37% by mass hydrochloric acid and 60% by mass nitric acid at a volume ratio of hydrochloric acid to the nitric acid of 2.6/1.4 to 3.4/0.6), ultrapure water, nitric acid (preferably 0.001% to 1% by mass nitric acid), perchloric acid (preferably 0.001% to 1% by mass perchloric acid), an aqueous oxalic acid solution (preferably a 0.01% to 10% by mass aqueous solution), or an aqueous periodic acid solution (preferably a 0.5% to 10% by mass aqueous periodic acid solution, examples of the periodic acid include orthoperiodic acid and metaperiodic acid) is preferable.

The preferred conditions required to FPM, SPM, APM, and HPM are the same as the suitable aspects of, for example, to FPM, SPM, APM, and HPM used as the specific solution described above.

The hydrofluoric acid, nitric acid, perchloric acid, and hydrochloric acid mean aqueous solutions obtained by dissolving HF, HNO₃, HClO₄, and HCl in water respectively.

The aqueous ozone, aqueous carbon dioxide, and aqueous hydrogen mean aqueous solutions obtained by dissolving O₃, CO₂, and H₂ in water respectively.

As long as the purpose of the rinsing step is not impaired, these rinsing liquids may be used by being mixed together.

Among the above, as the rinsing liquid, from the viewpoint of further reducing chlorine remaining on the surface of the substrate after the rinsing step, aqueous carbon dioxide, aqueous ozone, aqueous hydrogen, hydrofluoric acid, an aqueous citric acid solution, hydrochloric acid, sulfuric acid, aqueous ammonia, hydrogen peroxide water, SPM, APM, HPM, IPA, an aqueous hypochlorous acid solution, aqua regia, or FPM is preferable, and hydrofluoric acid, hydrochloric acid, hydrogen peroxide water, SPM, APM, HPM, or FPM is more preferable.

Examples of the specific method of the step C include a method of bringing the substrate as an object to be treated obtained by the step A into contact with the rinsing liquid.

The method of bringing the substrate into contact with the rinsing liquid is performed by immersing the substrate in the rinsing liquid put in a tank, spraying the rinsing liquid on the substrate, causing the rinsing liquid to flow on the substrate, or a method composed of an any combination of these.

The treatment time (contact time between the rinsing liquid and the object to be treated) is not particularly limited, and is 5 seconds to 5 minutes for example.

The temperature of the rinsing liquid during the treatment is not particularly limited. Generally, the temperature of the rinsing liquid is preferably 16° C. to 60° C., and more preferably 18° C. to 40° C. In a case where SPM is used as the rinsing liquid, the temperature thereof is preferably 90° C. to 250° C.

### Step D

As necessary, the present treatment method may have a step D of performing a drying treatment after the step C.

The method of the drying treatment is not particularly limited, and examples thereof include spin drying, causing a drying gas to flow on the substrate, heating the substrate by a heating unit (for example, heating by a hot plate or an infrared lamp), isopropyl alcohol (IPA) vapor drying, Marangoni drying, Rotagoni drying, and a combination of these.

The drying time can be appropriately changed depending on the specific method to be used. For example, the drying time is about 30 seconds to a few minutes.

### Method of Manufacturing Semiconductor Device

The method for treating an object can be suitably applied to a method for manufacturing a semiconductor device.

The treatment method may be carried out in combination before or after other steps performed on a substrate. The treatment method may be incorporated into other steps while carrying out the treatment method, or the treatment method may be incorporated into the other steps.

Examples of those other steps include a step of forming a structure such as a metal wire, a gate structure, a source structure, a drain structure, an insulating film, a ferromagnetic layer, and a non-magnetic layer (for example, layer formation, etching, chemical mechanical polishing, and modification), a resist forming step, an exposure step and a removing step, a heat treatment step, a cleaning step, and an inspection step.

The treatment method may be performed at any stage in a back-end-of-the-line (BEOL) process, a middle-of-the-line (MOL) process, a front-end-of the line (FEOL) process, and is preferably performed in the front-end-of the line process or the middle-of-the-line process.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Accordingly, the scope of the present invention should not be construed as being limited to the Examples described below.

### Preparation of Composition

After mixing ultrapure water with each component to obtain a mixed solution so as to have the contents shown in Tables 1 to 3 in the latter part, the mixed solution was sufficiently stirred with a stirrer to obtain a composition used in each of Examples and Comparative Examples.

The contents of the compositions in Tables 1 to 3 are based on mass, and the remainder of the total of the respective components is ultrapure water. In addition, in the composition of Comparative Example 6, hexafluorosilicic acid was used instead of the compound corresponding to the quaternary ammonium salt, and 5-phenyltetrazole was used instead of the compound corresponding to the nonionic surfactant.

Hereinafter, each component shown in Tables 1 to 3 in the latter part will be specifically described.

### Periodic Acid or Salt Thereof

IO-1: orthoperiodic acid
IO-2: sodium orthoperiodate
IO-3: metaperiodic acid

### Quaternary Ammonium Salt

A-1: tetramethylammonium hydroxide
B-1: tetraethylammonium hydroxide
B-2: tetraethylammonium chloride
B-3: tetraethylammonium bromide
B-4: tetraethylammonium fluoride
C-1: tetrabutylammonium hydroxide
D-1: ethyltrimethylammonium hydroxide
D-2: ethyltrimethylammonium chloride
E-1: diethyldimethylammonium hydroxide
F-1: triethylmethylammonium hydroxide
G-1: t (2-hydroxyethyl) trimethylammonium hydroxide
H-1: tributylmethylammonium hydroxide
I-1: dimethyldipropylammonium hydroxide
J-1: benzyltrimethylammonium hydroxide
K-1: benzyltriethylammonium hydroxide
L-1: triethyl (2-hydroxyethyl) ammonium hydroxide

### Ionic Surfactant

T-1: sodium dodecylbenzene sulfonate
T-2: dodecylbenzene sulfonic acid
T-3: branched sodium dodecylbenzene sulfonate
T-4: p-octylbenzene sulfonic acid
T-5: monoisopropyl naphthalene sulfonate·sodium
T-6: sodium dioctyl sulfosuccinate
T-7: sodium dodecyl sulfate
T-8: octyl phosphate potassium
T-9: octyl ether phosphate potassium
T-10: lauryltrimethylammonium chloride
T-11: lauryl dimethylbenzylammonium chloride
T-12: alkyl polyaminoethyl glycine hydrochloride
T-13: lauryl betaine
T-14: lauryl dimethylamine oxide
T-15: hexadecyltrimethylammonium-p-toluene sulfonate

### Nonionic Surfactant

### (Polyoxyalkylene Alkyl Ether)

S-1: compound represented by the following structural formula

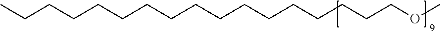

S-2: NIKKOL (registered trademark) SG-C420 (POE(20)POP(4) cetyl ether, HLB value: 16.5, manufactured by NIKKO CHEMICAL CO., LTD.)
S-3: TAKESURF (registered trademark) D-1420 (polyoxyethylene stearyl ether, HLB value: 15.3, manufactured by TAKEMOTO OIL & FAT Co., Ltd.)
S-4: EMULGEN (registered trademark) 2025G (polyoxyethylene octyldodecyl ether, HLB value: 15.7, manufactured by Kao Corporation)
S-5: EMULGEN (registered trademark) 104P (polyoxyethylene (4) lauryl ether, HLB value: 9.6, manufactured by Kao Corporation)
S-6: EMULGEN (registered trademark) 106 (polyoxyethylene (5) lauryl ether, HLB value: 10.5, manufactured by Kao Corporation)
S-7: EMULGEN (registered trademark) 108 (polyoxyethylene (6) lauryl ether, HLB value: 12.1, manufactured by Kao Corporation)
S-8: EMULGEN (registered trademark) 109P (polyoxyethylene (9) lauryl ether, HLB value: 13.6, manufactured by Kao Corporation)
S-9: EMULGEN (registered trademark) 123P (polyoxyethylene (23) lauryl ether, HLB value: 16.9, manufactured by Kao Corporation)
S-10: EMULGEN (registered trademark) 130K (polyoxyethylene (41) lauryl ether, HLB value: 18.1, manufactured by Kao Corporation)
S-11: EMULGEN (registered trademark) 210P (polyoxyethylene (7) cetyl ether, HLB value: 10.7, manufactured by Kao Corporation)
S-12: TAKESURF (registered trademark) D-1002 (polyoxyethylene octyl ether, HLB value: 8.1, manufactured by TAKEMOTO OIL & FAT Co., Ltd.)

### (Fatty Acid Ester)

S-13: RHEODOL (registered trademark) 440 (polyoxyethylene sorbitol fatty acid ester, HLB value: 11.8, manufactured by Kao Corporation)
S-14: NIKKOL (registered trademark) 430NV (polyoxyethylene sorbitol fatty acid ester, HLB value: 11.5, manufactured by NIKKO CHEMICAL CO., LTD.)
S-15: NIKKOL (registered trademark) 440V (polyoxyethylene sorbitol fatty acid ester, HLB value: 12.5, manufactured by NIKKO CHEMICAL CO., LTD.)
S-16: RHEODOL (registered trademark) 460 (polyoxyethylene sorbitol fatty acid ester, HLB value: 13.8, manufactured by Kao Corporation)
S-17: NIKKOL (registered trademark) 460V (polyoxyethylene sorbitol fatty acid ester, HLB value: 14.0, manufactured by NIKKO CHEMICAL CO., LTD.)
S-18: RHEODOL (registered trademark) TW-S120V (polyoxyethylene sorbitan fatty acid ester, HLB value: 14.9, manufactured by Kao Corporation)
S-19: RHEODOL (registered trademark) SP-L10 (a sorbitan fatty acid ester, HLB value: 8.6, manufactured by Kao Corporation)
S-20: RHEODOL (registered trademark) MS-165V (glycerin fatty acid ester, HLB value: 11.0, manufactured by Kao Corporation)

### (Other Nonionic Surfactants)

S-21: Triton (registered trademark) X-100 (polyethylene glycol mono-4-octylphenyl ether, HLB value: 13.4, manufactured by Dow Chemical Company)
S-22: Triton (registered trademark) X-405 (polyethylene glycol mono-4-octylphenyl ether, HLB value: 17.6, manufactured by Dow Chemical Company)
S-23: SURFYNOL (registered trademark) MD-20 (acetylene glycol, HLB value: 8.0, manufactured by Evonik Industries AG)

### Other Compounds

R-1: hexafluorosilicic acid
R-2: 5-phenyltetrazole

### Water

Ultrapure water

### Evaluation

In a case where an object to be treated, which contains Ru, was treated with the composition according to the embodiment of the present invention, the Ru removability was confirmed by the following procedure.

A substrate for evaluation was prepared by forming a Ru layer (a layer composed of a single Ru with a film thickness of 30 nm) by a PVD method at a position of 5 mm from the wafer edge on one surface of a commercially available silicon wafer (diameter: 12 inches).

By spraying the composition of each of Examples or Comparative Examples at a position 5 mm from the end part of the substrate using a single-wafer type cleaning device, a treatment of removing the Ru layer in the bevel portion of the substrate was carried out for a predetermined time. The temperature of the composition was 25° C.

The end part of the substrate after the treatment was observed with a scanning electron microscope (S4800, manufactured by Hitachi High-Tech Corporation) to confirm the presence or absence of the Ru layer. The time required to completely remove the Ru layer was measured, and the Ru removability was evaluated according to the following evaluation standard.

### (Evaluation Standard for Ru Removability)

A: Less than 0.5 minutes
B: 0.5 minutes or more and less than 1 minute
C: 1 minute or more and less than 2 minutes
D: 2 minutes or more and less than 3 minutes
E: 3 minutes or more and less than 5 minutes
F: 5 minutes or more

TABLE 1

| | Periodic acid | | Quaternary | | | | | | | |
|---|---|---|---|---|---|---|---|---|---|---|
| | or salt thereof | | ammonium salt | | Ionic surfactant | | Nonionic surfactant | | | |
| | | Content | | Content | | Content | | Content | | Ru |
| | Type | (mass %) | Type | (mass %) | Type | (ppm by mass) | Type | (ppm by mass) | pH | removability |
| Example 1 | IO-1 | 2 | B-1 | 1 | T-1 | 100 | S-1 | 300 | 6.9 | A |
| Example 2 | IO-1 | 2 | D-1 | 1 | T-2 | 300 | S-1 | 600 | 7.1 | A |
| Example 3 | IO-1 | 2 | B-1 | 1 | T-3 | 300 | S-16 | 600 | 6.5 | A |
| Example 4 | IO-1 | 2 | B-1 | 1 | T-4 | 300 | S-16 | 600 | 6.4 | A |
| Example 5 | IO-1 | 2 | D-1 | 1 | T-5 | 300 | S-16 | 600 | 6.3 | A |
| Example 6 | IO-1 | 2 | D-1 | 1 | T-6 | 300 | S-1 | 600 | 6.7 | B |
| Example 7 | IO-1 | 2 | B-1 | 1 | T-7 | 300 | S-16 | 600 | 6.2 | B |
| Example 8 | IO-1 | 2 | D-1 | 1 | T-8 | 300 | S-16 | 600 | 6.5 | C |
| Example 9 | IO-1 | 2 | D-1 | 1 | T-9 | 300 | S-1 | 600 | 6.0 | C |
| Example 10 | IO-1 | 2 | D-1 | 1 | T-10 | 300 | S-1 | 600 | 6.1 | D |
| Example 11 | IO-1 | 2 | B-1 | 1 | T-11 | 300 | S-1 | 600 | 6.9 | D |
| Example 12 | IO-1 | 2 | B-1 | 1 | T-12 | 300 | S-16 | 600 | 7.1 | D |
| Example 13 | IO-1 | 2 | D-1 | 1 | T-13 | 300 | S-1 | 600 | 7.0 | D |
| Example 14 | IO-1 | 2 | D-1 | 1 | T-14 | 300 | S-16 | 600 | 6.2 | D |
| Example 15 | IO-1 | 2 | D-1 | 1 | T-1 | 300 | S-2 | 600 | 6.4 | A |
| Example 16 | IO-1 | 2 | B-1 | 1 | T-2 | 300 | S-3 | 600 | 6.3 | A |
| Example 17 | IO-1 | 2 | D-1 | 1 | T-1 | 300 | S-4 | 600 | 6.7 | B |
| Example 18 | IO-1 | 2 | D-1 | 1 | T-1 | 300 | S-5 | 600 | 6.2 | B |
| Example 19 | IO-1 | 2 | D-1 | 1 | T-1 | 300 | S-6 | 600 | 6.4 | B |
| Example 20 | IO-1 | 2 | B-1 | 1 | T-2 | 300 | S-7 | 600 | 6.3 | A |
| Example 21 | IO-1 | 2 | B-1 | 1 | T-1 | 300 | S-8 | 600 | 6.7 | A |
| Example 22 | IO-1 | 2 | D-1 | 1 | T-1 | 300 | S-9 | 600 | 6.2 | A |
| Example 23 | IO-1 | 2 | B-1 | 1 | T-1 | 300 | S-10 | 600 | 6.5 | B |
| Example 24 | IO-1 | 2 | D-1 | 1 | T-1 | 300 | S-11 | 600 | 6.4 | A |
| Example 25 | IO-1 | 2 | D-1 | 1 | T-2 | 300 | S-12 | 600 | 6.3 | D |
| Example 26 | IO-1 | 2 | D-1 | 1 | T-1 | 300 | S-13 | 600 | 6.7 | A |
| Example 27 | IO-1 | 2 | D-1 | 1 | T-2 | 300 | S-14 | 600 | 6.2 | A |
| Example 28 | IO-1 | 2 | B-1 | 1 | T-1 | 300 | S-15 | 600 | 6.4 | A |
| Example 29 | IO-1 | 2 | D-1 | 1 | T-1 | 300 | S-16 | 600 | 6.3 | A |
| Example 30 | IO-1 | 2 | D-1 | 1 | T-1 | 300 | S-17 | 600 | 6.4 | A |
| Example 31 | IO-1 | 2 | D-1 | 1 | T-1 | 300 | S-18 | 600 | 6.3 | A |
| Example 32 | IO-1 | 2 | B-1 | 1 | T-1 | 300 | S-19 | 600 | 6.7 | C |
| Example 33 | IO-1 | 2 | B-1 | 1 | T-2 | 300 | S-20 | 600 | 6.2 | A |
| Example 34 | IO-1 | 2 | D-1 | 1 | T-1 | 300 | S-21 | 600 | 6.5 | A |
| Example 35 | IO-1 | 2 | D-1 | 1 | T-1 | 300 | S-22 | 600 | 6.4 | A |
| Example 36 | IO-1 | 2 | B-1 | 1 | T-1 | 300 | S-23 | 600 | 6.3 | E |

TABLE 2

| | Periodic acid | | Quaternary | | | | | | | |
|---|---|---|---|---|---|---|---|---|---|---|
| | or salt thereof | | ammonium salt | | Ionic surfactant | | Nonionic surfactant | | | |
| | | Content | | Content | | Content | | Content | | Ru |
| | Type | (mass %) | Type | (mass %) | Type | (ppm by mass) | Type | (ppm by mass) | pH | removability |
| Example 37 | IO-3 | 2 | B-1 | 1 | T-1 | 100 | S-1 | 300 | 6.2 | A |
| Example 38 | IO-2 | 2 | D-1 | 1 | T-2 | 300 | S-1 | 600 | 7.1 | A |
| Example 39 | IO-1 | 2 | A-1 | 1 | T-1 | 300 | S-16 | 600 | 6.4 | A |
| Example 40 | IO-1 | 2 | C-1 | 1 | T-1 | 300 | S-1 | 600 | 6.3 | B |
| Example 41 | IO-1 | 2 | E-1 | 1 | T-2 | 300 | S-16 | 600 | 6.7 | A |
| Example 42 | IO-1 | 2 | F-1 | 1 | T-2 | 300 | S-16 | 600 | 6.2 | A |
| Example 43 | IO-1 | 2 | G-1 | 1 | T-1 | 300 | S-1 | 600 | 6.4 | A |
| Example 44 | IO-1 | 2 | H-1 | 1 | T-1 | 300 | S-1 | 600 | 6.3 | A |
| Example 45 | IO-1 | 2 | I-1 | 1 | T-1 | 300 | S-1 | 600 | 6.7 | A |
| Example 46 | IO-1 | 2 | J-1 | 1 | T-1 | 300 | S-16 | 600 | 6.2 | A |
| Example 47 | IO-1 | 2 | K-1 | 1 | T-2 | 300 | S-1 | 600 | 6.4 | A |
| Example 48 | IO-1 | 2 | L-1 | 1 | T-1 | 300 | S-16 | 600 | 6.4 | A |
| Example 49 | IO-1 | 2 | B-2 | 1 | T-1 | 300 | S-1 | 600 | 6.4 | B |
| Example 50 | IO-1 | 2 | D-2 | 1 | T-2 | 300 | S-1 | 600 | 6.3 | B |
| Example 51 | IO-1 | 2 | B-3 | 1 | T-1 | 300 | S-1 | 600 | 6.4 | C |
| Example 52 | IO-1 | 2 | B-4 | 1 | T-1 | 300 | S-16 | 600 | 6.3 | C |
| Example 53 | IO-1 | 2 | D-1 | 0.2 | T-2 | 300 | S-1 | 600 | 1.2 | C |
| Example 54 | IO-1 | 2 | D-1 | 0.31 | T-1 | 300 | S-1 | 600 | 3.0 | B |
| Example 55 | IO-1 | 2 | B-1 | 0.82 | T-2 | 300 | S-1 | 600 | 4.5 | A |
| Example 56 | IO-1 | 2 | B-1 | 1.2 | T-1 | 300 | S-1 | 600 | 7.2 | A |
| Example 57 | IO-1 | 2 | D-1 | 1.8 | T-2 | 300 | S-1 | 600 | 8.9 | A |
| Example 58 | IO-1 | 2 | B-1 | 2 | T-1 | 300 | S-1 | 600 | 9.7 | B |
| Example 59 | IO-1 | 2 | D-1 | 2.5 | T-2 | 300 | S-1 | 600 | 10.7 | C |
| Example 60 | IO-1 | 2 | D-1 | 3.2 | T-1 | 300 | S-16 | 600 | 12.5 | D |
| Example 61 | IO-1 | 0.05 | B-1 | 0.02 | T-1 | 300 | S-1 | 600 | 6.7 | D |
| Example 62 | IO-1 | 0.2 | D-1 | 0.09 | T-2 | 300 | S-16 | 600 | 6.2 | A |
| Example 63 | IO-1 | 5 | D-1 | 2.7 | T-1 | 300 | S-16 | 600 | 6.5 | A |
| Example 64 | IO-1 | 7.5 | B-1 | 3.9 | T-1 | 300 | S-1 | 600 | 6.4 | B |
| Example 65 | IO-1 | 11 | D-1 | 5 | T-2 | 300 | S-1 | 600 | 6.3 | C |
| Example 66 | IO-1 | 16 | D-1 | 8.2 | T-1 | 300 | S-1 | 600 | 6.7 | E |

TABLE 3

| | Periodic acid | | Quaternary | | | | | | | |
|---|---|---|---|---|---|---|---|---|---|---|
| | or salt thereof | | ammonium salt | | Ionic surfactant | | Nonionic surfactant | | | |
| | | Content | | Content | | Content | | Content | | Ru |
| | Type | (mass %) | Type | (mass %) | Type | (ppm by mass) | Type | (ppm by mass) | pH | removability |
| Example 67 | IO-1 | 2 | D-1 | 1 | T-2 | 8 | S-16 | 24 | 6.2 | C |
| Example 68 | IO-1 | 2 | B-1 | 1 | T-1 | 20 | S-1 | 100 | 6.4 | B |
| Example 69 | IO-1 | 2 | B-1 | 1 | T-2 | 75 | S-1 | 80 | 6.3 | B |
| Example 70 | IO-1 | 2 | D-1 | 1 | T-1 | 100 | S-1 | 200 | 6.7 | A |
| Example 71 | IO-1 | 2 | D-1 | 1 | T-1 | 500 | S-16 | 800 | 6.2 | A |
| Example 72 | IO-1 | 2 | B-1 | 1 | T-2 | 1000 | S-1 | 1000 | 6.5 | A |
| Example 73 | IO-1 | 2 | B-1 | 1 | T-1 | 1200 | S-16 | 1500 | 6.4 | B |
| Example 74 | IO-1 | 2 | D-1 | 1 | T-1 | 4800 | S-16 | 6000 | 6.3 | B |
| Example 75 | IO-1 | 2 | D-1 | 1 | T-2 | 6100 | S-1 | 7500 | 6.7 | C |
| Example 76 | IO-1 | 2 | D-1 | 1 | T-1 | 8000 | S-1 | 9000 | 6.2 | D |
| Example 77 | IO-1 | 2 | B-1 | 1 | T-1 | 11000 | S-1 | 13000 | 6.4 | E |
| Example 78 | IO-1 | 2 | D-1 | 1 | T-1 | 100 | S-16 | 5 | 6.4 | C |
| Example 79 | IO-1 | 2 | D-1 | 1 | T-1 | 100 | S-16 | 10 | 6.3 | B |
| Example 80 | IO-1 | 2 | B-1 | 1 | T-1 | 100 | S-1 | 50 | 6.7 | B |
| Example 81 | IO-1 | 2 | D-1 | 1 | T-2 | 100 | S-16 | 100 | 6.2 | A |
| Example 82 | IO-1 | 2 | D-1 | 1 | T-1 | 100 | S-16 | 500 | 6.4 | A |
| Example 83 | IO-1 | 2 | B-1 | 1 | T-1 | 100 | S-1 | 1000 | 6.4 | A |
| Example 84 | IO-1 | 2 | B-1 | 1 | T-1 | 100 | S-16 | 1500 | 6.3 | B |
| Example 85 | IO-1 | 2 | D-1 | 1 | T-2 | 100 | S-16 | 3000 | 6.7 | C |
| Example 86 | IO-1 | 2 | D-1 | 1 | T-1 | 100 | S-1 | 12000 | 6.2 | E |
| Example 87 | IO-1 | 1.5 | B-1 | 1 | T-2 | 100 | S-1 | 300 | 6.9 | A |
| | IO-3 | 0.5 | | | | | | | | |
| Example 88 | IO-1 | 2 | B-1 | 0.8 | T-2 | 100 | S-1 | 300 | 6.9 | A |
| | | | D-1 | 0.2 | | | | | | |
| Example 89 | IO-1 | 2 | B-1 | 1 | T-2 | 80 | S-1 | 300 | 6.9 | A |
| | | | | | T-3 | 20 | | | | |
| Example 90 | IO-1 | 2 | B-1 | 1 | T-2 | 100 | S-1 | 400 | 6.9 | A |
| | | | | | | | S-16 | 200 | | |
| Comparative | — | — | B-1 | 1 | T-1 | 100 | S-1 | 100 | 6.3 | F |
| Example 1 | | | | | | | | | | |
| Comparative | IO-1 | 2 | — | — | T-1 | 100 | S-1 | 100 | 4.4 | F |
| Example 2 | | | | | | | | | | |
| Comparative | IO-1 | 2 | D-1 | 1 | — | — | S-1 | 100 | 6.2 | F |
| Example 3 | | | | | | | | | | |
| Comparative | IO-1 | 2 | B-1 | 1 | T-1 | 100 | — | — | 6.7 | F |
| Example 4 | | | | | | | | | | |
| Comparative | IO-1 | 2 | B-1 | 1 | — | — | S-22 | 100 | 6.3 | F |
| Example 5 | | | | | | | S-12 | 100 | | |
| Comparative | IO-1 | 0.125 | R-1 | 0.4 | T-15 | 50 | R-2 | 30 | 1.2 | F |
| Example 6 | | | | | | | | | | |

As is clear from the results of Tables 1 to 3, it was confirmed that the composition of Examples of the present invention has excellent Ru removability.

On the other hand, in Comparative Examples 1 to 4 in which any one of the nonionic surfactant, the at least one ionic surfactant selected from the group consisting of periodic acid or a salt thereof, a quaternary ammonium salt, an anionic surfactant, a cationic surfactant, and an amphoteric surfactant was not included, sufficient Ru removability was not obtained.

In addition, in Comparative Example 5 in which two or more kinds of nonionic surfactants were contained but an anionic surfactant was not contained, sufficient Ru removability was not obtained.

In addition, in Comparative Example 6 corresponding to the aspect of US2017/0260449A, sufficient Ru removability was not obtained.

In addition, from the results of Tables 1 to 3, it was confirmed that in a case where the ionic surfactant in the composition was an anionic surfactant, the Ru removability was more excellent (comparison between Examples 1 to 9 and Examples 10 to 14).

It was confirmed that in a case where the anionic surfactant has a sulfonic acid group, the Ru removability is further excellent (comparison between Examples 1 to 7 and Examples 8 and 9), and in a case where the anionic surfactant has a cyclic structure, the Ru removability is particularly excellent (comparison between Examples 1 to 5 and Examples 6 and 7).

From the results of Tables 1 to 3, it was confirmed that in a case where the nonionic surfactant in the composition includes a polyoxyalkylene alkyl ether, a polyoxyalkylene alkyl aryl ether, or a fatty acid ester, the Ru removability is more excellent (comparison between Example 36 and Examples 21, 28, and 32, and the like).

It was confirmed that in a case where the nonionic surfactant has a polyoxyethylene chain or a polyoxypropylene chain, the Ru removability is more excellent (comparison between Example 31 and Example 32, and the like).

It was confirmed that in a case where the nonionic surfactant has a monovalent hydrocarbon group having 10 to 18 carbon atoms, the Ru removability is more excellent (comparison between Example 15 and Example 17, and the like).

It was confirmed that in a case where the HLB value of the nonionic surfactant is 9.0 to 20.0, the Ru removability is more excellent (comparison between Examples 18, 19, and 23, and Example 25, and the like), and in a case where the HLB value is 11.0 to 18.0, the Ru removability is further excellent (comparison between Example 15, and Examples 18, 19, and 23, and the like).

From the results of Tables 1 to 3, it was confirmed that in a case where the quaternary ammonium salt includes, in the composition, at least one selected from the group consisting of a tetramethylammonium salt, a tetraethylammonium salt, a tetrabutylammonium salt, an ethyltrimethylammonium salt, a tricthylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl) trimethylammonium salt, and a triethyl (2-hydroxyethyl) ammonium salt, the Ru removability is more excellent (comparison between Example 39 and Examples 49 and 51, and the like).

From the results of Tables 1 to 3, it was confirmed that the Ru removability was more excellent in a case where the pH of the composition was 3.0 to 10.0 (comparison between Examples 55 and 57 and Examples 53 and 59, and the like).

From the results of Tables 1 to 3, it was confirmed that in a case where the content of the periodic acid or a salt thereof is 0.01% to 15.00% by mass with respect to the total mass of the composition, the Ru removability is more excellent (comparison of Examples 61 to 66, and the like); in a case where the content of the periodic acid or a salt thereof is 0.1% to 10.00% by mass with respect to the total mass of the composition, the Ru removability is still more excellent (comparison of Examples 61 to 66, and the like); and in a case where the content of the periodic acid or a salt thereof is 0.10% to 5.00% by mass with respect to the total mass of the composition, the Ru removability is particularly excellent (comparison of Examples 61 to 66, and the like).

From the results in Tables 1 to 3, it was confirmed that in a case where the content of the ionic surfactant was 10 to 5,000 ppm by mass with respect to the total mass of the composition, the Ru removability was more excellent (the comparison between Example 74 and Example 75, and the like). In addition, it was confirmed that in a case where the content of the ionic surfactant was 100 to 1,000 ppm by mass, the Ru removability was further excellent (comparison between Example 72 and Example 73, and the like).

From the results of Tables 1 to 3, it was confirmed that in a case where the mass ratio of the content of the nonionic surfactant to the content of the ionic surfactant is 0.1 to 100, the Ru removability is more excellent (the comparison between Example 85 and Example 86, and the like). In addition, it was confirmed that in a case where the mass ratio is 1 to 10, the Ru removability is further excellent (comparison between Example 83 and Example 84, and the like).

It was confirmed that even in a case where a mixture containing the following compounds LAS-10 to LAS-13 at a mass ratio of LAS-10:LAS-11:LAS-12:LAS-13=10:35:30:25 was used as an ionic surfactant instead of T-2 used in Example 2 in Table 1 and the evaluation was carried out, the same effect as that of the composition described in Example 2 was obtained.

In other examples in which T-2 was used, the same effects as those of each example were obtained in a case where the above-described mixture was used instead of T-2.

In addition, it was confirmed that even in a case where a mixture containing the following compounds LAS-10 to LAS-13 in a mass ratio of LAS-10:LAS-11:LAS-12:LAS-13=10:35:30:25 was used as the ionic surfactant instead of T-3 used in Example 3 in Table 1 and the above-described evaluation was carried out, the same effect as that of the composition described in Example 3 was obtained.

In addition, in other examples in which T-3 was used, the same effects as those in each example were obtained in a case where the above-described mixture was used instead of T-3.

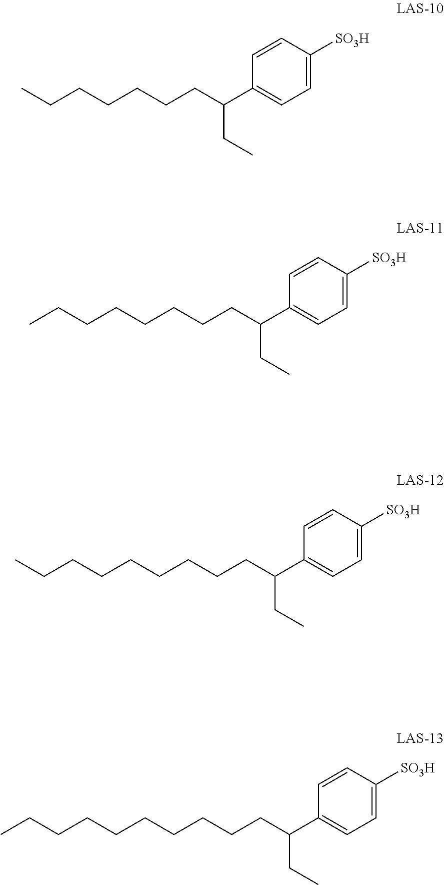 [SMILES: CCCCCCCC(CC)c1ccc(S(=O)(=O)O)cc1 ; CCCCCCCCC(CC)c1ccc(S(=O)(=O)O)cc1 ; CCCCCCCCCC(CC)c1ccc(S(=O)(=O)O)cc1 ; CCCCCCCCCCC(CC)c1ccc(S(=O)(=O)O)cc1]

### EXPLANATION OF REFERENCES

10a, 10b: Ru wiring board
12: insulating film
14: barrier metal layer
16: Ru-containing wiring line
18: recess portion
20a, 20b: Ru liner substrate
22: insulating film
24: Ru-containing liner
26: wiring portion
28: recess portion
30: object to be treated
32: substrate
34: Ru-containing film
36: outer edge portion
40: object to be treated
42: substrate
44: Ru-containing film
46: etching stop layer
48: interlayer insulating film
50: metal hard mask
52: groove or the like
54: interior wall
54a: cross-sectional wall
54b: bottom wall
56: dry etching residue
60a, 60b: object to be treated
62: insulating film
64: metal hard mask
66: Ru-containing film
72: groove or the like
74a: cross-sectional wall
74b: bottom portion
76: dry etching residue
80a, 80b: object to be treated
82: insulating film
84: metal hard mask
86: groove or the like
88: Ru-containing film
90a: cross-sectional wall
90b: bottom wall
92: residue

What is claimed is:

1. A composition comprising:
a periodic acid or a salt thereof;
a quaternary ammonium salt;
at least one ionic surfactant selected from the group consisting of an anionic surfactant, a cationic surfactant, and an amphoteric surfactant; and
a nonionic surfactant.

2. The composition according to claim 1,
wherein the ionic surfactant is an anionic surfactant.

3. The composition according to claim 2,
wherein the anionic surfactant has at least one of a sulfonic acid group or a phosphoric acid group.

4. The composition according to claim 2,
wherein the anionic surfactant has a cyclic structure.

5. The composition according to claim 1,
wherein the nonionic surfactant includes a polyoxyalkylene alkyl ether, a polyoxyalkylene alkyl aryl ether, or a fatty acid ester.

6. The composition according to claim 1,
wherein the nonionic surfactant has a polyoxyalkylene chain composed of an oxyalkylene group selected from the group consisting of an oxyethylene group and an oxypropylene group.

7. The composition according to claim 1,
wherein the nonionic surfactant has a polyoxyethylene chain or a polyoxypropylene chain.

8. The composition according to claim 7,
wherein the nonionic surfactant has a monovalent hydrocarbon group having 10 to 18 carbon atoms.

9. The composition according to claim 1,
wherein an HLB value of the nonionic surfactant is 9.0 to 20.0.

10. The composition according to claim 1,
wherein the periodic acid or a salt thereof includes at least one selected from the group consisting of orthoperiodic acid, metaperiodic acid, and salts thereof.

11. The composition according to claim 1,
wherein the quaternary ammonium salt includes at least one compound selected from the group consisting of a tetramethylammonium salt, a tetraethylammonium salt, a tetrabutylammonium salt, an ethyltrimethylammonium salt, a methyltriethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt, and a triethyl (2-hydroxyethyl)ammonium salt.

12. The composition according to claim 1, further comprising:
water.

13. The composition according to claim 1,
wherein a pH of the composition is 3.0 to 10.0.

14. The composition according to claim 1,
wherein the composition does not substantially contain coarse particles.

15. A method for treating an object to be treated, comprising:
a step of bringing an object to be treated, which contains ruthenium, into contact with the composition according to claim 1.

16. A manufacturing method for a semiconductor device, comprising:
the method for treating an object to be treated according to claim 15.

17. A method for treating an object to be treated, comprising:
a step of bringing an object to be treated, which contains ruthenium, into contact with the composition according to claim 2.

18. A method for treating an object to be treated, comprising:
a step of bringing an object to be treated, which contains ruthenium, into contact with the composition according to claim 3.

19. A method for treating an object to be treated, comprising:
a step of bringing an object to be treated, which contains ruthenium, into contact with the composition according to claim 4.

20. A method for treating an object to be treated, comprising:
a step of bringing an object to be treated, which contains ruthenium, into contact with the composition according to claim 5.
